(19) United States
(12) Patent Application Publication
(10) Pub. No.: US 2025/0126770 A1
(43) Pub. Date: Apr. 17, 2025

(54) SRAM CELL, MEMORY INCLUDING SRAM CELL, AND ELECTRONIC DEVICE

(71) Applicant: INSTITUTE OF MICROELECTRONICS, CHINESE ACADEMY OF SCIENCES, Beijing (CN)

(72) Inventors: Huilong Zhu, Poughkeepsie, NY (US); Xinhao Li, Beijing (CN)

(21) Appl. No.: 18/670,024

(22) Filed: May 21, 2024

(30) Foreign Application Priority Data
Oct. 17, 2023 (CN) 202311345962.6

(51) Int. Cl. H10B 10/00

(52) U.S. Cl. CPC H10B 10/125

(57) ABSTRACT

Provided are a static random access memory (SRAM) cell, a memory, and an electronic device. The SRAM cell may include a first pull-up transistor, a second pull-up transistor, a first pull-down transistor, a second pull-down transistor, a first pass-gate transistor, and a second pass-gate transistor on a substrate. The first and second pull-up transistors are provided at a first height relative to the substrate. The first and second pull-down transistors and the first and second pass-gate transistors are provided at a second height different from the first height relative to the substrate. Each of the transistors includes a channel nanosheet extending in a first direction and source/drain portions provided above and below the channel nanosheet respectively. The first pull-down transistor is aligned with the first pull-up transistor in a vertical direction, and the second pull-down transistor is aligned with the second pull-up transistor in the vertical direction.

### CROSS-REFERENCE TO RELATED APPLICATIONS

This application is claims priority to Chinese Application No. 2023113459626 filed on Oct. 17, 2023, which is incorporated herein by reference in its entirety.

### TECHNICAL FIELD

The present disclosure relates to a field of semiconductors, and in particular to a static random access memory (SRAM) cell, a method of manufacturing the SRAM cell, a memory including the SRAM cell, and an electronic device.

### BACKGROUND

In a planar device such as a Metal Oxide Semiconductor Field Effect Transistor (MOSFET), a source, a gate and a drain are arranged in a direction substantially parallel to a substrate surface. Due to such an arrangement, the planar device is difficult to be further scaled down. In contrast, in a vertical device, a source, a gate and a drain are arranged in a direction substantially perpendicular to a substrate surface. As a result, the vertical device is easier to be scaled down compared to the planar device.

In addition, it is desired to improve an integration level to increase a memory density, so the vertical device has promising applications in memory devices such as a static random access memory (SRAM).

### SUMMARY

In view of above, the object of the present disclosure is at least partially to provide a static random access memory (SRAM) cell with an improved performance, a method of manufacturing the SRAM cell, a memory including the SRAM cell, and an electronic device.

According to an aspect of the present disclosure, an SRAM cell is provided, including: a first pull-up transistor, a second pull-up transistor, a first pull-down transistor, a second pull-down transistor, a first pass-gate transistor, and a second pass-gate transistor on a substrate. The first pull-up transistor and the second pull-up transistor are provided at a first height relative to the substrate. The first pull-down transistor, the second pull-down transistor, the first pass-gate transistor, and the second pass-gate transistor are provided at a second height different from the first height relative to the substrate. Each of the first pull-down transistor, the second pull-down transistor, the first pass-gate transistor, and the second pass-gate transistor includes a channel nanosheet extending in a first direction, as well as source/drain portions provided above and below the channel nanosheet respectively. Each of the first pull-up transistor and the second pull-up transistor includes a channel nanosheet extending in a first direction, as well as source/drain portions provided above and below the channel nanosheet respectively. The first pull-down transistor is aligned with the first pull-up transistor in a vertical direction, and the second pull-down transistor is aligned with the second pull-up transistor in the vertical direction.

According to another aspect of the present disclosure, a method of manufacturing the SRAM cell is provided, including: sequentially providing, on a substrate, a stack of a first group including a first source/drain layer, a channel layer, and a second source/drain layer as well as a second group including a first source/drain layer, a channel layer, and a second source/drain layer; forming a hard mask layer on the stack, wherein the hard mask layer includes main body parts and a connecting part between the main body parts, the main body parts are used to define transistors included in the SRAM cell, the connecting part is used to define an interconnection structure included in the SRAM cell, a line width of the connecting part is less than a line width of the main body part, the main body parts are in a rectangular shape, and at least one main body part may have a width different from other main body parts; defining, using the hard mask layer, active regions of a pull-down transistor and a pass-gate transistor in the transistors included in the SRAM cell in the channel layer and second source/drain layer of the second group; defining, using the hard mask layer, a first interconnection structure and a second interconnection structure in the interconnection structure included in the SRAM cell in the first source/drain layer of the second group and the second source/drain layer of the first group; and defining, using the hard mask layer, an active region of a pull-up transistor in the transistors included in the SRAM cell in the channel layer and first source/drain layer of the first group.

According to another aspect of the present disclosure, a memory is provided, including the above-mentioned SRAM cell.

According to another aspect of the present disclosure, an electronic device is provided, including the memory having the above-mentioned SRAM cell.

According to an embodiment of the present disclosure, the constituent transistors of the SRAM cell may be arranged in a vertically stacked manner, thereby saving area. The transistors in the upper and lower layers may be stacked in a self-aligned manner, thereby further saving area. The active region of the transistor, especially the channel material, may be a single crystal semiconductor material, thereby providing a high mobility and thus enhancing the performance of the SRAM cell. In addition, the size of each constituent transistor in the SRAM cell may be freely adjusted, which is conductive to subsequent design techniques to collaborate and optimize (DTCO).

### BRIEF DESCRIPTION OF THE DRAWINGS

The above and other objects, features, and advantages of the present disclosure will become more apparent through following description on embodiments of the present disclosure with reference to accompanying drawings, in which:

FIG. 1 schematically shows an equivalent circuit diagram of a static random access memory (SRAM) cell;

FIG. 2 schematically shows a perspective view of an SRAM cell according to an embodiment of the present disclosure;

FIGS. 3(a) and 3(b) show decomposed perspective views of the SRAM cell shown in FIG. 2;

FIGS. 4 to 37(c) schematically show some stages in a process of manufacturing an SRAM cell according to an embodiment of the present disclosure.

Throughout the accompanying drawings, the same or similar reference numbers denote the same or similar components.

### DETAILED DESCRIPTION OF EMBODIMENTS

Hereinafter, embodiments of the present disclosure will be described with reference to accompanying drawings. However, it should be understood that these descriptions are illustrative and not intended to limit the scope of the present disclosure. Further, in the following, descriptions for known structures and technologies are omitted to avoid obscuring the concept of the present disclosure unnecessarily.

Various structures according to the embodiments of the present disclosure are shown in the accompanying drawings. However, they are not drawn to scale, and some features may be enlarged while some features may be omitted for sake of clarity. Shapes, relative sizes and positions of regions and layers shown in the drawings are only illustrative, and deviations may occur due to manufacture tolerances or technique limitations in practice. In addition, those skilled in the art may devise regions/layers of other different shapes, sizes, and relative positions as desired in practice.

In the context of the present disclosure, when a layer/element is recited as being “on” a further layer/element, the layer/element may be disposed directly on the further layer/element, or otherwise there may be an intervening layer/element interposed therebetween. Further, if a layer/element is “on” a further layer/element in an orientation, then the layer/element may be “under” the further layer/element when the orientation is turned.

According to an embodiment of the present disclosure, a static random access memory (SRAM) cell based on a vertical nanosheet metal oxide semiconductor field-effect transistor (MOSFET) is provided. In the SRAM cell, vertical devices as the constituent elements of the SRAM cell may be stacked in the vertical direction to further enhance integration. In addition, the size of each constituent transistor in the SRAM cell may be freely adjusted, which is conductive to subsequent design techniques to collaborate and optimize (DTCO).

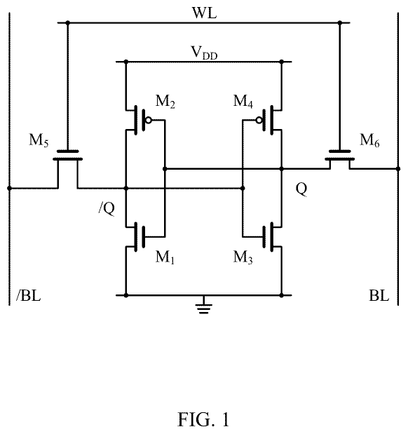

FIG. 1 schematically shows an equivalent circuit diagram of an SRAM cell.

As shown in FIG. 1, the SRAM cell may have a 6T structure, that is, the SRAM cell includes 6 constituent transistors M₁ to M₆, such as field-effect transistors (FET). Among these 6 transistors, four transistors M₁, M₂, M₃, and M₄ may form two cross-coupled inverters as storage positions for one bit in the SRAM cell. The other two transistors M₅ and M₆ may control the data transmission between the storage position and the bit line BL as well as the complementary bit line/BL under the control of the word line WL, respectively, to achieve reading and writing.

Among the four transistors M₁, M₂, M₃, and M₄ that form the cross-coupled inverters, two p-type transistors M₂ and M₄ may be connected to the power supply voltage V_{DD}, and may thus be referred to as “pull-up transistors” (PU); two n-type transistors M₁ and M₃ may be connected to the ground voltage and may thus be referred to as “pull-down transistors” (PD). The transistors M₅ and M₆ (which may also be n-type) may control reading/writing or data transmission, and may thus be referred to as “access control transistors” or “pass-gate transistors” (PG).

Hereinafter, read and write operations of such 6T SRAM cell are briefly described.

The read operation is described firstly. Assuming that the bit stored in the storage position is “1”, that is, high level is at the node Q while the low level is at the node /Q. At the beginning of the read cycle, the bit line BL and the complementary bit line /BL may be pre-charged as logic 1, and then the word line WL may be charged with high level, so that the access control transistors M₅ and M₆ are turned on. Due to the high level at Q, the pull-up transistor M₂ is turned off while the pull-down transistor M₁ is turned on. Accordingly, the pull-down transistor M₁ and the access control transistor M₅ connect the complementary bit line /BL to ground. Therefore, the pre-charged value of the complementary bit line /BL is flushed out, resulting in a zero value on the complementary bit line /BL. On the other hand, due to the low level at /Q, the pull-up transistor M₄ is turned on while the pull-down transistor M₃ is turned off. Accordingly, the pull-up transistor M₄ and the access control transistor M₆ connect the bit line BL to the power supply voltage V_{DD}, and thus maintain the pre-charged value, which is 1 on the bit line BL. If the stored bit is “0”, the opposite circuit state may result in the complementary bit line /BL with a value of 1 and a bit line BL with a value of 0. By distinguishing which of the bit line BL and the complementary bit line /BL has a higher potential, the stored bit “0” or “1” may be read out.

In the write operation, at the beginning of the write cycle, the state to be written is loaded into the bit line BL. For example, if “0” is to be written, the bit line BL is set to “0” (and the complementary bit line /BL is set to “1”). Then the word line WL may be charged with high level, so that the access control transistors M₅ and M₆ are turned on, and thus the state of the bit line BL is loaded into the storage position of the SRAM cell. This is achieved by designing the bit line input driver (transistor) to be stronger than the storage position (transistor), so that the state of the bit line may cover the previous state of the cross-coupled inverter in the storage position.

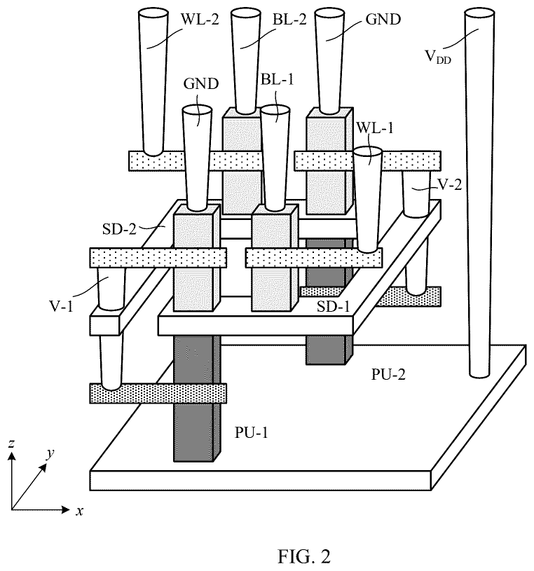

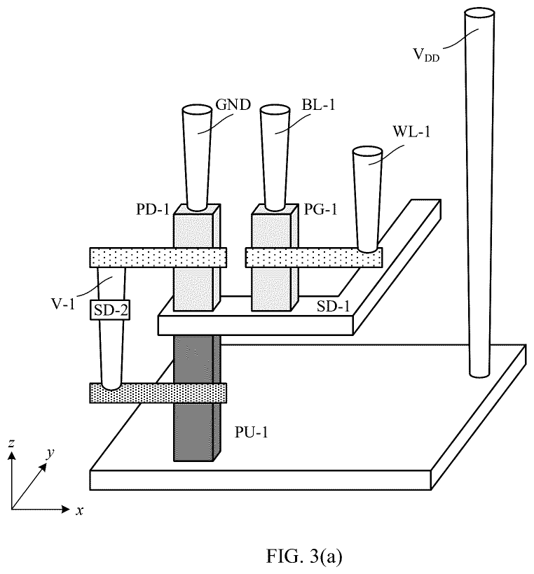

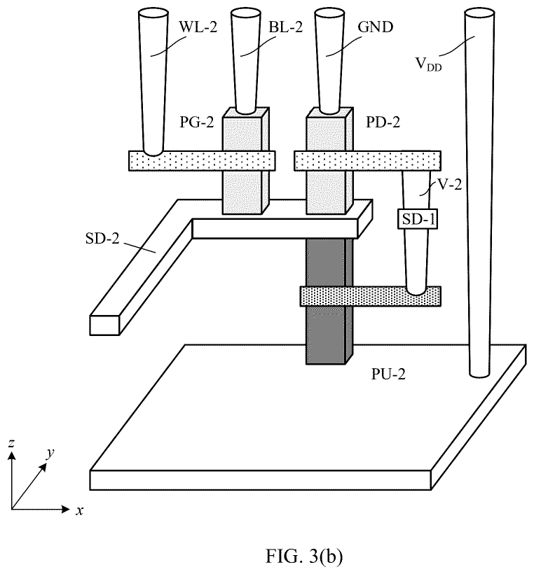

FIG. 2 schematically shows a perspective view of an SRAM cell according to an embodiment of the present disclosure. FIGS. 3(a) and 3(b) show decomposed perspective views of the SRAM cell shown in FIG. 2.

As shown in FIGS. 2, 3(a), and 3(b), the 6T SRAM cell may include 6 transistors, specifically, two pull-up transistors PU-1 and PU-2, two pull-down transistors PD-1 and PD-2, and two pass-gate transistors PG-1 and PG-2. These transistors may all be vertical nanosheet transistors.

Each transistor may include an active region extending in a vertical direction (e.g. a direction substantially perpendicular to the substrate surface) relative to the upper surface of the substrate. The active region may include a channel region and source/drain regions located on opposite sides of the channel region in the vertical direction. As described below, the active region of the transistor may include a first source/drain layer, a channel layer, and a second source/drain layer stacked sequentially in the vertical direction. The layers may be adjacent to each other, or other semiconductor layer(s), such as a leakage suppression layer and an on-state current enhancement layer (a semiconductor layer with a bandgap greater or less than adjacent layers), may be provided therebetween. The source/drain regions may be substantially formed in the first source/drain layer and the second source/drain layer respectively, while the channel region may be substantially formed in the channel layer. For example, the source/drain region may be achieved through the doping region in the source/drain layer. A gate stack may be formed around at least some or even the entire periphery of the channel region. For the sake of illustration convenience, the position of the gate stack is schematically shown in the perspective view using the gate electrode included in the gate stack, and the gate electrode is only shown in a cross-sectional form.

As shown, the active region, especially the channel layer, may be in a form of nanosheet. The nanosheet may have a width in the first direction (e.g. x direction), a thickness in the second direction (e.g. y direction) that intersects with (e.g. perpendicular to) the first direction, and a certain height in the vertical direction (e.g. z direction). The first and second directions may be transverse directions (substantially parallel to the substrate surface). Generally, the width of the nanosheet is greater than the thickness of the nanosheet. The first source/drain layer and the second source/drain layer may be self-aligned with the channel layer in the vertical direction and may also be in the form of nanosheet.

According to an embodiment of the present disclosure, among the nanosheets acting as channel portions (e.g. channel layers, and thus also referred to as the “channel nanosheets”) of the pull-down transistors PD-1 and PD-2 as well as the pass-gate transistors PG-1 and PG-2, at least one channel nanosheet may have a width different from the width of other channel nanosheets. The channel nanosheets of the pull-down transistors PD-1 and PD-2 may have substantially the same width (“first width”), while the channel nanosheets of the pass-gate transistors PG-1 and PG-2 may have substantially the same width (“second width”). The first width may be different from, for example, greater than the second width, for example, by a predetermined times (for example, 2 or 3 times). Of course, their widths may also be set to be substantially the same.

The pull-up transistors PU-1 and PU-2 may be self-aligned with the pull-down transistors PD-1 and PD-2 in the vertical direction, respectively. The widths of the channel nanosheets of the pull-up transistors PU-1 and PU-2 may be substantially the same as or may be different from the widths of the channel nanosheets of the pull-down transistors PD-1 and PD-2, respectively.

According to an embodiment of the present disclosure, such transistor may be a conventional FET. In the case of conventional FET, the source/drain regions on both sides of the channel region may have doping of the same conductivity type (e.g. n-type or p-type). A conductive channel may be formed between the source/drain regions located at both ends of the channel region through the channel region. Alternatively, such transistor may be a tunneling FET. In the case of tunneling FET, the source/drain regions on both sides of the channel region may have doping of different conductivity types (e.g. n-type and p-type, respectively). In this case, charged particles such as electrons may tunnel through the channel region from the source region and enter the drain region, so as to form a conduction path between the source region and the drain region. Although the conventional FET and the tunneling FET are different in conduction mechanism, they both exhibit an electrical property that the conduction between the source/drain regions is controlled through the gate. Therefore, for the conventional FET and the tunneling FET, the terms “source/drain layer (source/drain region)” and “channel layer (channel region)” are uniformly used for description, although there is no typical “channel” in the tunneling FET.

Unlike the conventional SRAM cell where the constituent transistors are arranged in a planar layout, the constituent transistors in the SRAM cell according to the embodiments of the present disclosure may be stacked in the vertical direction to further save the area occupied by the SRAM cell.

According to an embodiment, transistors with the same conductivity type may be provided in one layer (for example, have substantially the same height relative to the upper surface of the substrate). Transistors with different conductivity types may be provided in two layers respectively (for example, have different heights relative to the upper surface of the substrate), and these two layers may at least partially overlap in the vertical direction.

In the examples shown in FIGS. 2, 3(a), and 3(b), the pull-up transistors PU-1 and PU-2, which serve as p-type transistors, are provided in one layer, while the pull-down transistors PD-1 and PD-2 and the pass-gate transistors PG-1 and PG-2, which serve as n-type transistors, are provided in one layer. In this example, the p-type transistors are in the lower layer, while the n-type transistors are in the upper layer. However, the present disclosure is not limited to this. For example, by flipping the structures shown in FIGS. 2, 3(a), and 3(b) up and down (with the substrate still at the bottom) and adjusting the interconnection structure accordingly, the p-type transistor may be in the upper layer while the n-type transistor may be in the lower layer.

Due to the relatively complex electrical connections to the pull-down transistors PD-1 and PD-2 and the pass-gate transistors PG-1 and PG-2 as n-type transistors, it is advantageous to provide the n-type transistors in the upper layer, for example, to facilitate the fabrication of electrical connections. In the accompanying drawings and the following description, the n-type transistors provided in the upper layer are used as an example.

Such transistors may be electrically connected to each other according to the above-mentioned 6T arrangement.

As shown in FIGS. 2, 3(a), and 3(b), the upper source/drain region (e.g. drain region) of the first pull-up transistor PU-1 may be connected to the lower source/drain region (e.g. drain region) of the first pull-down transistor PD-1. The first node between the upper source/drain region of the first pull-up transistor PU-1 and the lower source/drain region of the first pull-down transistor PD-1 corresponds to the node Q shown in FIG. 1. The lower source/drain region of the first pass-gate transistor PG-1 may be connected to the first node, while the upper source/drain region of the first pass-gate transistor PG-1 may be connected to the first bit line (e.g., the bit line BL in FIG. 1) through the corresponding contact plug BL-1. Here, the connections between the source/drain regions of the first pull-up transistor PU-1, the first pull-down transistor PD-1, and the first pass-gate transistor PG-1 are shown as the first interconnection structure SD-1. Similarly, the upper source/drain region (e.g. drain region) of the second pull-up transistor PU-2 may be connected to the lower source/drain region (e.g. drain region) of the second pull-down transistor PD-2. The second node between the upper source/drain region of the second pull-up transistor PU-2 and the lower source/drain region of the second pull-down transistor PD-2 corresponds to the node /Q shown in FIG. 1. The lower source/drain region of the second pass-gate transistor PG-2 may be connected to the second node, while the upper source/drain region of the second pass-gate transistor PG-2 may be connected to the second bit line (e.g., the bit line /BL in FIG. 1) through the corresponding contact plug BL-2. Here, the connections between the source/drain regions of the second pull-up transistor PU-2, the second pull-down transistor PD-2, and the second pass-gate transistor PG-2 are shown as the second interconnection structure SD-2. As described below, the first interconnection structure SD-1 and the second interconnection structure SD-2 may not necessarily be separate conductive layers, but may also be achieved through the material layers (such as the source/drain layers mentioned above) where the source/drain regions of the transistor are located.

The gate electrodes of the first pull-up transistor PU-1 and the first pull-down transistor PD-1 may be electrically connected to each other through the third interconnection structure V-1. The third interconnection structure V-1 may be electrically connected to the second interconnection structure SD-2 (for example, as described below, they may be integrated, equivalent to being jointly connected to the node /Q). Similarly, the gate electrodes of the second pull-up transistor PU-2 and the second pull-down transistor PD-2 may be electrically connected to each other through the fourth interconnection structure V-2. The fourth interconnection structure V-2 may be electrically connected to the first interconnection structure SD-1 (for example, as described below, they may be integrated, equivalent to being jointly connected to the node Q).

The lower source/drain region (e.g. source region) of each of the first pull-up transistor PU-1 and the second pull-up transistor PU-2 may be provided on the substrate to receive the power supply voltage V_{DD} through a contact plug to the substrate. The upper source/drain region (e.g. source region) of each of the first pull-down transistor PD-1 and the second pull-down transistor PD-2 may receive the ground voltage GND through a corresponding contact plug. The gate electrode of each of the first pass-gate transistor PG-1 and the second pass-gate transistor PG-2 may be electrically connected to the word line (e.g., the word line WL shown in FIG. 1) through corresponding contact plugs WL-1 and WL-2, respectively.

As shown in FIGS. 3(a) and 3(b), based on the first and second nodes, the six constituent transistors may be divided into two groups: the first pull-up transistor PU-1, the first pull-down transistor PD-1, and the first pass-gate transistor PG-1 (see FIG. 3(a)), which are jointly connected to the first node, as well as the second pull-up transistor PU-2, the second pull-down transistor PD-2, and the second pass-gate transistor PG-2 (see FIG. 3(b)), which are jointly connected to the second node. These two groups may have the same or symmetrical arrangement (the arrangement shown in FIG. 3(b) may be obtained by rotating the arrangement shown in FIG. 3(a) 180°). However, the present disclosure is not limited to this. These two groups may have different or asymmetric arrangements.

According to an embodiment of the present disclosure, an active material layer for the p-type transistor and an active material layer for the n-type transistor may be sequentially provided on the substrate. For example, the active material layers may be provided through epitaxial growth. For example, the first source/drain layer, the channel layer, and the second source/drain layer for the p-type transistor, as well as the first source/drain layer, the channel layer, and the second source/drain layer for the n-type transistor, may be sequentially grown. Accordingly, the active material layers may be formed as single crystal semiconductor materials. The single crystal semiconductor material is conductive to providing a high mobility.

According to an embodiment of the present disclosure, for example, the gate length may be determined by the thickness of the channel layer through the self-alignment process described below. The channel layer may be formed through epitaxial growth, so the thickness of the channel layer may be well controlled. Therefore, the gate length may be well controlled. For example, the gate length may be controlled to be relatively small (such as less than about 10 nm).

The active region of the n-type transistor and the interconnection pattern in the upper layer may be defined from top to bottom in the active material layer for the n-type transistor, and the active region of the p-type transistor and the interconnection pattern in the lower layer may be defined in the active material layer for the p-type transistor. To achieve vertical overlap between transistors for saving area, the same mask pattern or mask layer may be used to define the active patterns in the upper and lower layers. According to an embodiment of the present disclosure, each of the first interconnection structure, the second interconnection structure, as well as the third interconnection structure and the fourth interconnection structure, may be defined by the source/drain layer (for example, the second source/drain layer for the p-type transistor and the first source/drain layer for the n-type transistor) between the upper and lower layers. In this case, the first to fourth interconnection structures may be silicified to reduce or avoid the influence of adjacent source/drain layers on interconnection performance caused by pn junctions formed by doping of different conductivity types. Then, the p-type transistor may be fabricated in the lower layer. When the p-type transistor is fabricated, the occupying layer may be used to cover the active region of the n-type transistor in the upper layer. When the fabrication of p-type transistor is completed, an isolation layer may be used to cover the lower layer, and then the n-type transistor may be fabricated in the upper layer.

For the convenience of gate replacement process, the occupying layer (also known as “sacrificial gate”) for the gate stack may include materials different from those of the occupying layers at other positions. In this way, the sacrificial gate may then be removed and a gate stack may be formed in the space left due to the removal of the sacrificial gate.

To facilitate the formation of such sacrificial gate or occupying layer, defining of active region may be separately performed for the channel layer and the source/drain layer. For example, the active region may be defined in the channel layer first (for example, the channel layer may be divided into channel portions for transistors, which may be in the form of nanosheet). Then, the occupying layer (sacrificial gate) may be formed. Due to the continuous extension of the source/drain layers on both sides of the channel layer at this time, the occupying layer (sacrificial gate) formed in this way may be self-aligned with the channel layer, so as to subsequently form a self-aligned gate stack through the gate replacement process. The pattern of the occupying layer (sacrificial gate) may be further adjusted to achieve the electrical connection and/or isolation required by the gate stack, which would be subsequently formed by replacing the occupying layer (sacrificial gate). Then, in the source/drain layer, the active region may be defined and the occupying layer may be formed likewise.

According to an embodiment, the first interconnection structure and the second interconnection structure may be achieved through the source/drain layers between two layers. Therefore, when patterning the active region, the second source/drain layer for the p-type transistor and the first source/drain layer for the n-type transistor may be patterned according to the arrangements of the first interconnection structure and the second interconnection structure. In view of this, the mask pattern used to define the active region may include a part (such as a rectangular part) used to define the active region of the transistor, a part (such as a circular part) used to define the third and fourth interconnection structures, and a part (the connection line between the rectangular or circular parts mentioned above) used to define the first and second interconnection structures. As described below, such mask pattern may be grid like.

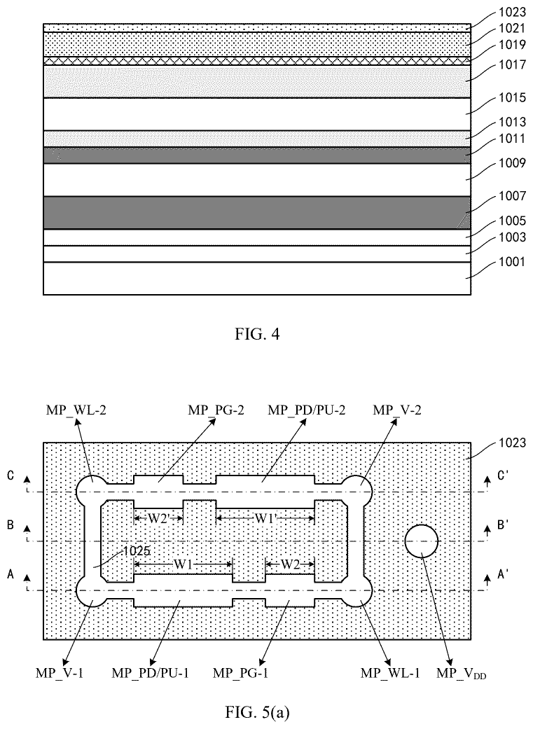

FIGS. 4 to 37(c) schematically show some stages in a process of manufacturing an SRAM cell according to an embodiment of the present disclosure.

In the following description, the materials of various layers are listed. However, these are just examples. The materials of various layers are mainly determined based on their functions (such as semiconductor materials used to provide active regions, dielectric materials used to provide gap filling and electrical isolation, etc.) and the required etching selectivity. In the description, sometimes it may not be explicitly stated which materials in a certain layer have etching selectivity relative to those in other layers, or simply mention “required etching selectivity”. Such “required etching selectivity” may be at least partially determined by the relevant etching process.

As shown in FIG. 4, a substrate 1001 is provided. The substrate 1001 may be a substrate in various forms. The substrate 1001 may include a semiconductor material, such as but not limited to, a bulk semiconductor material such as a bulk Si, a Semiconductor On Insulator (SOI), a compound semiconductor such as SiGe, or the like. In the following description, the bulk Si substrate will be described by way of example for the convenience of description. In the substrate 1001, a well region (not shown) may be formed as needed, for example, by injecting impurities. In an example where a p-type transistor is provided in the lower layer, the injected impurities may be n-type impurities.

A contact layer 1003 may be formed on the substrate 1001 to assist in connecting to a source/drain region of a transistor (such as a p-type pull-up transistor) in the lower layer in the SRAM cell on a side close to the substrate. The contact layer 1003 may be formed by injecting impurities into an upper part of the substrate 1001. In the example where the p-type transistor is provided in the lower layer, the injected impurities may be p-type impurities such as B or In, with a concentration in a range of 1E18 cm⁻³ to 1E21 cm⁻³, such as 1.5E20 cm⁻³. Of course, the contact layer 1003 may be additionally formed on the substrate 1001 by epitaxial growth.

An isolation auxiliary layer 1005 may be formed on the contact layer 1003 by, for example, epitaxial growth. The isolation auxiliary layer 1005 may help achieve electrical isolation between the third and fourth interconnection structures and the contact layer at a desired position, which will be further described in detail below. In addition, to facilitate the electrical connection between the contact layer 1003 and the source/drain region of the p-type transistor formed above (for example, to reduce the resistance when applying a potential, such as the V_{DD} mentioned above, to the source/drain region of the p-type transistor), the isolation auxiliary layer 1005 may have n-type conductivity by in-situ doping during growth or injecting impurities, such as As with a concentration of 2E18 cm⁻³, after growth.

An active material layer may be provided on the isolation auxiliary layer 1005. For example, a first source/drain layer 1007, a channel layer 1009, and a second source/drain layer 1011 for the p-type transistor, as well as a first source/drain layer 1013, a channel layer 1015, and a second source/drain layer 1017 for the n-type transistor may be sequentially formed by epitaxial growth. These layers may have the required conductivity by in-situ doping during growth or injecting impurities after growth.

Adjacent layers among semiconductor material layers formed on the substrate 1001 may have etching selectivity relative to each other, except for the second source/drain layer 1011 for the p-type transistor and the first source/drain layer 1013 for the n-type transistor. The second source/drain layer 1011 for the p-type transistor and the first source/drain layer 1013 for the n-type transistor may have no etching selectivity or relatively low etching selectivity relative to each other, because in subsequent processing, they are almost processed as the same layer except for being doped into different conductivity types to serve as the source/drain regions for the p-type transistor and the n-type transistor, respectively. In addition, for the p-type transistor, the first source/drain layer 1007 and the second source/drain layer 1011 may include the same material. Similarly, for the n-type transistor, the first source/drain layer 1013 and the second source/drain layer 1017 may include the same material.

In an example, these semiconductor material layers may include a stack of Si alternated with SiGe. For example, in a case where the substrate 1001 (including the contact layer 1003 formed therein) is Si, the isolation auxiliary layer 1005 may include SiGe with a thickness in a range of 5 nm to 20 nm. For the p-type transistor, the first source/drain layer 1007 may include Si with a thickness in a range of 20 nm to 50 nm; the channel layer 1009 may include SiGe (with an atomic percentage of Ge, for example, in a range of 10% to 40%) with a thickness in a range of 10 nm to 100 nm; and the second source/drain layer 1011 may include Si with a thickness in a range of 10 nm to 30 nm. The first source/drain layer 1007 and the second source/drain layer 1011 may be p-doped (e.g. doped with B), with a doping concentration in a range of 1E19 cm⁻³ to 1E21 cm⁻³ (e.g. 1.5E20 cm⁻³). Similarly, for the n-type transistor, the first source/drain layer 1013 may include Si with a thickness in a range of 10 nm to 30 nm; the channel layer 1015 may include SiGe (with an atomic percentage of Ge, for example, in a range of 10% to 70%) with a thickness in a range of 10 nm to 100 nm; and the second source/drain layer 1017 may include Si with a thickness in a range of 20 nm to 50 nm. The first source/drain layer 1013 and the second source/drain layer 1017 may be n-doped (e.g. doped with As), with a doping concentration in a range of 1E19 cm⁻³ to 1E21 cm⁻³ (e.g. 2.5E20 cm⁻³).

In addition, the channel layer may also be doped to adjust a threshold voltage (Vₜ) of the transistor. For the p-type transistor, the channel layer 1009 may be n-type doped (e.g. doped with As), with a doping concentration in a range of 1E17 cm⁻³ to 2E18 cm⁻³ (e.g. 2E18 cm⁻³). For the n-type transistor, the channel layer 1015 may be p-type doped (e.g. doped with B), with a doping concentration in a range of 1E17 cm⁻³ to 2E18 cm⁻³ (e.g. 2E18 cm⁻³). For a tunneling FET, the channel layer may be doped to the same conductivity type as the corresponding first source/drain layer or second source/drain layer. Of course, the channel layer may be unintentionally doped.

A hard mask may be provided on the active material layer to subsequently define the active region and the interconnection pattern. For example, an aluminum oxide (Al₂O₃) layer 1019 (or a silicon carbide layer) with a thickness in a range of 2 nm to 10 nm, a nitride (e.g. silicon nitride) layer 1021 with a thickness in a range of 10 nm to 100 nm, and an oxide (e.g. silicon oxide) layer 1023 with a thickness in a range of 10 nm to 100 nm may be sequentially formed by deposition. The provision of the hard mask is to provide purposes such as appropriate pattern definitions and etching stops in subsequent processes. The number of layers in the hard mask and the materials of the layers may vary according to the process. In this example, the layer configuration of the hard mask may ensure that (at least one layer in) the hard mask may be retained at least until the fabrication of transistors is completed.

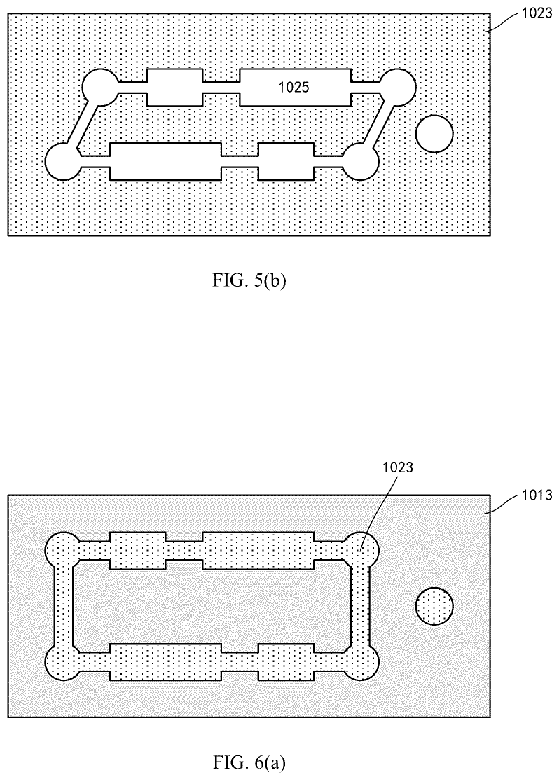

As shown in FIG. 5(a), a photoresist 1025 may be formed on the hard mask. The photoresist 1025 may be formed into a certain pattern through exposure and development. Here, the pattern may include a part (e.g. in rectangular) used to define the active region of the transistor, a part (e.g. in circular or square) used to define the third and fourth interconnection structures, and a part (e.g. a connection line between the aforementioned parts) used to define the first and second interconnection structures.

Such pattern may be divided into two columns corresponding to the above-mentioned two groups. These two columns may extend parallel to the first direction (e.g. a horizontal direction within the paper surface in FIG. 5) and be separated in the second direction (e.g. a vertical direction within the paper surface in FIG. 5) intersecting with (e.g. perpendicular to) the first direction. In the example of FIG. 5(a), the lower column corresponds to the first pull-up transistor PU-1, the first pull-down transistor PD-1, and the first pass-gate transistor PG-1 that are jointly connected to the first node, while the upper column corresponds to the second pull-up transistor PU-2, the second pull-down transistor PD-2, and the second pass-gate transistor PG-2 that are jointly connected to the second node.

As shown, each column of the pattern may have two rectangular parts in the middle and two circular parts at both ends. More specifically, the lower column may sequentially include from left to right: a circular part MP_V-1 used to define the third interconnection structure V-1, a rectangular part MP_PD/PU-1 used to define the first pull-down transistor PD-1 (and the first pull-up transistor PU-1 vertically aligned with the first pull-down transistor PD-1), a rectangular part MP_PG-1 used to define the first pass-gate transistor PG-1, and a circular part MP_WL-1 used to define a contact plug WL-1. Similarly, the upper column may sequentially include from right to left: a circular part MP_V-2 used to define the fourth interconnection structure V-2, a rectangular part MP_PD/PU-2 used to define the second pull-down transistor PD-2 (and the second pull-up transistor PU-2 vertically aligned with the second pull-down transistor PD-2), a rectangular part MP_PG-2 used to define the second pass-gate transistor PG-2, and a circular part MP_WL-1 used to define a contact plug WL-2. Such rectangular or circular parts may be connected to each other through linear parts. Such linear parts (along with the circular or rectangular parts mentioned above) may define the first and second interconnection structures. More specifically, in the figure, the lower and right edges of the closed quadrilateral may define the first interconnection structure SD-1, while the upper and left edges may define the second interconnection structure SD-2. In addition, the pattern may further include a circular part MP_V_{DD} used to define a contact plug applying a power supply voltage V_{DD}. A line width (e.g. diameter) of the circular part and a line width (e.g. size in the second direction) of the rectangular part may be greater than a line width (e.g. size in the second direction) of the linear part.

In this mask pattern, a width W1 of the rectangular part MP_PD/PU-1 in the first direction may be greater than a width W2 of the rectangular part MP_PG-1 in the first direction. However, the rectangular part MP_PD/PU-1 and the rectangular part MP_PG-1 may have substantially the same size in the second direction and may be aligned with each other in the first direction. Similarly, a width W1′ of the rectangular part MP_PD/PU-2 in the first direction may be greater than a width W2′ of the rectangular part MP_PG-1 in the first direction. However, the rectangular part MP_PD/PU-2 and the rectangular part MP_PG-1 may have substantially the same size in the second direction and may be aligned with each other in the first direction. In addition, the width W1 of the rectangular part MP_PD/PU-1 in the first direction may be substantially equal to the width W1′ of the rectangular part PD/PU-2 in the first direction, and the width W2 of the rectangular part MP_PG-1 in the first direction may be substantially equal to the width W2′ of the rectangular part MP_PG-2 in the first direction.

It is to be noted that although W1=W1′>W2=W2′ is used as an example for description here, the present disclosure is not limited to this. For example, W1 may be different from W1′, and/or W2 may be different from W2′; and the relationship therebetween may also be changed. The widths W1, W1′, W2, and W2′ of rectangular parts may be determined differently based on design optimization, and W1=W1′=W2=W2′ is also possible in some cases.

Here, the circular part MP_V_{DD} is further incorporated into the mask pattern. However, the present disclosure is not limited to this. Such contact plug may be formed separately. In this case, the mask pattern may be substantially quadrilateral (in this example, rectangular).

In addition, the circular parts MP_WL-1 and MP_WL-2 are further incorporated into the mask pattern, which helps to form a contact plug self-aligned with a gate stack of the pass-gate transistor. However, the present disclosure is not limited to this. For example, the contact plug self-aligned with the gate stack of the pass-gate transistor may be formed separately. In this case, one circular part may be reduced in each of the two columns.

It should be noted that the positioning of each rectangular and circular part in the mask pattern (located at the edges and corners of the rectangle) is to achieve a more compact arrangement. However, their positioning may be changed.

In an example shown in FIG. 5(a), a substantial right angle may be formed between the intersecting linear parts, so that the linear parts form a substantial rectangular shape. However, the present disclosure is not limited to this. For example, as shown in FIG. 5(b), other angles, such as about 60° or 120°, may be formed between the intersecting linear parts, which may further save area while keeping the spacing between circular or rectangular parts unchanged.

The pattern of the photoresist 1025 may be transferred to the hard mask and subsequently to the active material layer below.

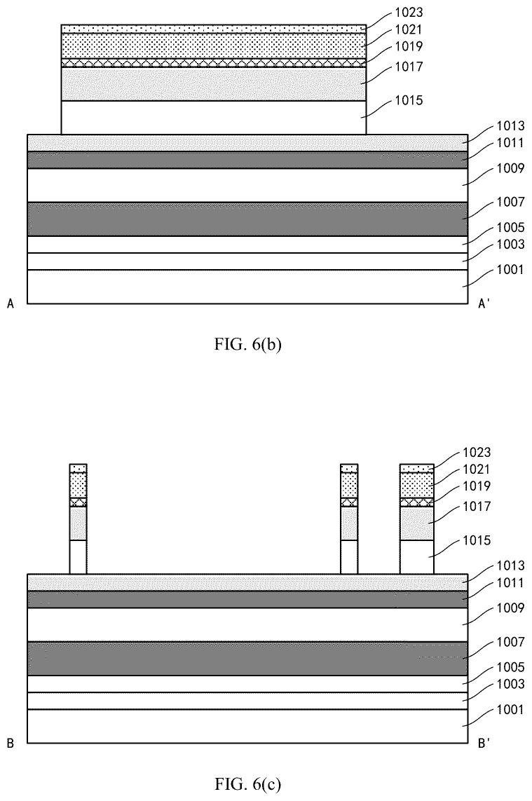

As shown in FIGS. 6(a), 6(b), and 6(c) (which are the top view and the cross-sectional views along line AA′ and line BB′, respectively), the hard mask (including the oxide layer 1023, the nitride layer 1021, and the aluminum oxide layer 1019), as well as the second source/drain layer 1017 and the channel layer 1015 for the n-type transistor may be sequentially etched by reactive ion etching (RIE), for example, by using the photoresist 1025 as the etching mask. RIE may be performed in a direction substantially perpendicular to the substrate surface and may be stopped at the first source/drain layer 1013 for the n-type transistor. In this example, the patterning of the active material layer of the n-type transistor is not performed to the first source/drain layer 1013, which is mainly due to the following reasons. On the one hand, in this example, the first source/drain layer 1013 for the n-type transistor may maintain a substantially identical pattern with the second source/drain layer 1011 for the p-type transistor, thereby allowing for subsequent patterning with the second source/drain layer 1011 for the p-type transistor. On the other hand, the second source/drain layer 1017 may be separated subsequently, and if the first source/drain layer 1013 is also etched here, then the first source/drain layer 1013 may also be divided into separate parts, which is unfavorable for forming the first and second interconnection structures. Afterwards, the photoresist 1025 may be removed.

In this way, the active region (the rectangular parts in the top view of FIG. 6(a)) of the n-type transistor is substantially defined in the upper layer. However, these rectangular parts (as well as circular parts) are currently connected to each other through linear parts, as shown in the cross-sectional view of FIG. 6(b). These rectangular parts may be separated to define the active regions of n-type transistors separately.

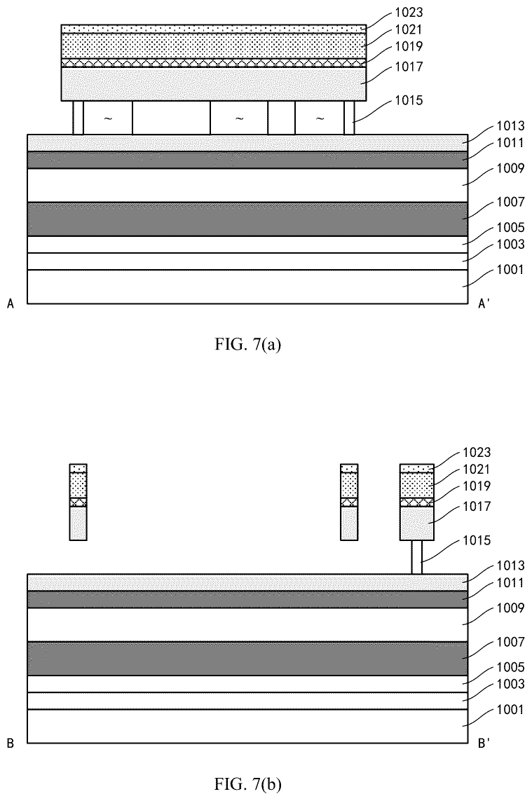

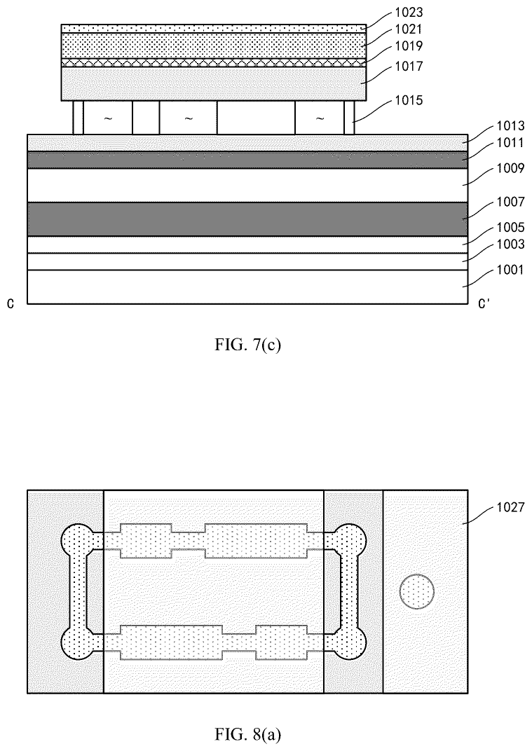

For example, as shown in FIGS. 7(a), 7(b), and 7(c) (which are the cross-sectional views along line AA′, line BB′, and line CC′ respectively), due to the etching selectivity of the channel layer 1015 relative to the source/drain layers 1013 and 1017, the channel layer 1015 may be further selective etched. Selective etching may be achieved using atomic layer etching (ALE) for precise and controllable etching. The degree of etching may be chosen to remove the linear parts, while a part (such as the center part) of the circular or rectangular part may be left. Accordingly, the channel layer 1015 may be divided into several separate parts corresponding to the circular or rectangular parts in the mask pattern (the circular parts in the mask pattern lead to the nanowires in the channel layer 1015, while the rectangular parts in the mask pattern lead to the nanosheets in the channel layer 1015). On the other hand, the source/drain layer 1017 may maintain the mask pattern and thus provide a self-aligned gate space for the n-type transistor (in combination with the source/drain layer 1013 below).

In this example, without considering anisotropy, it is assumed that the selective etching on the channel layer 1015 is substantially isotropic. Accordingly, in the top view, the etched channel layer 1015 still in a circular or rectangular shape substantially, and is (centrally) aligned with the corresponding circular or rectangular part in the mask pattern in the vertical direction.

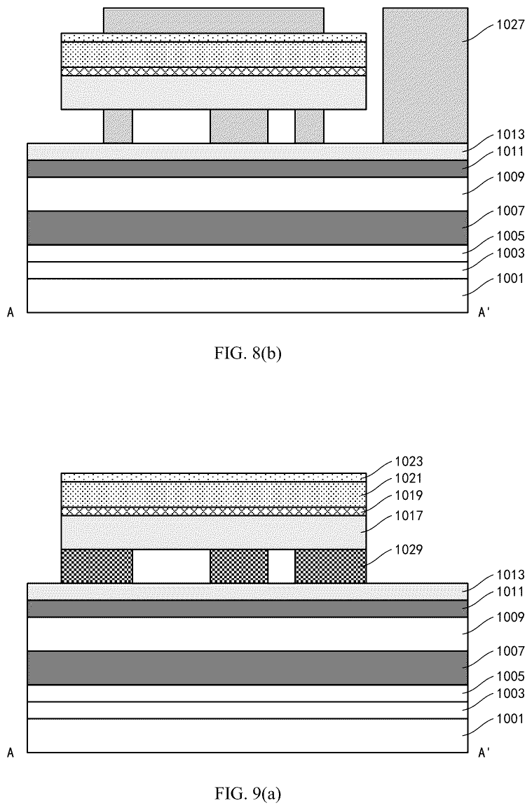

At the positions corresponding to the circular parts MP_WL-1 and MP_WL-2 as well as the circular parts MP_V-1 and MP_V-2 in the mask pattern, the nanowires in the channel layer 1015 may be omitted because no channel portion is needed (to form the transistor). Therefore, the nanowires in the channel layer at the positions corresponding to the circular parts MP_WL-1 and MP_WL-2 as well as the circular parts MP_V-1 and MP_V-2 in the mask pattern, may be removed. For example, as shown in FIGS. 8(a) and 8(b) (which are the top view and the cross-sectional view along line AA′, respectively), a photoresist 1027 may be formed on the above structure and patterned to expose the nanowires (the nanowires at the four corners in the top view of FIG. 8(a)) in the channel layer to be removed, and to cover the remaining nanosheets in the channel layer. The photoresist 1027 may be used as an etching mask to selectively etch the exposed nanowires in the channel layer for removing the nanowires. Afterwards, the photoresist 1027 may be removed.

It should be noted that although it is not necessary to provide nanowires in the channel layer 1015 at the position corresponding to the circular part MP_V_{DD} in the mask pattern (because transistors are not required here), the nanowires here may not be removed in order to avoid the collapse of the material layer.

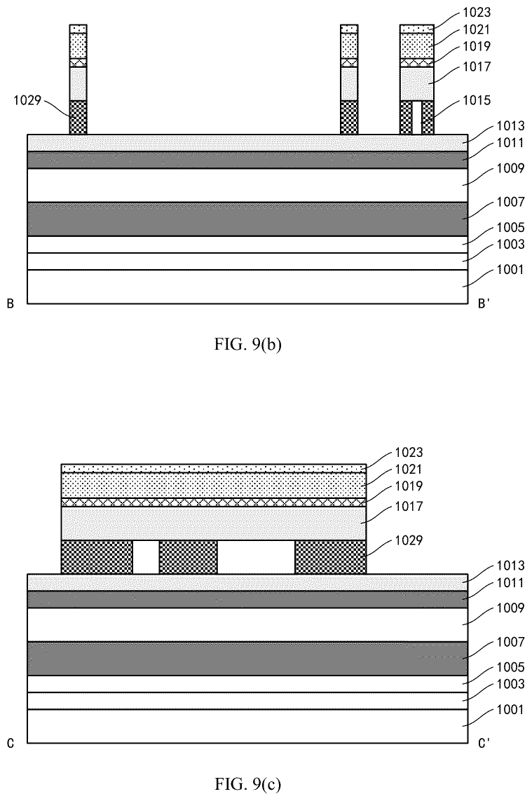

The gate stack may be formed subsequently in a recess of each nanosheet (i.e., the channel nanosheet) in the channel layer 1015 relative to the periphery of the hard mask. To avoid the impact of subsequent processing on the channel layer 1015 or leaving unnecessary materials in the recess that may affect the subsequent formation of the gate stack, an occupying layer may be formed in the recess to occupy the space for the gate stack (therefore, the material layer may be referred to as a “sacrificial gate”). For example, as shown in FIGS. 9(a), 9(b), and 9(c) (which are the cross-sectional views along line AA′, line BB′, and line CC′ respectively), a sacrificial gate 1029 may be formed by depositing materials with required etching selectivity (such as relative to the hard mask and the occupying layer), such as nitrogen oxide (e.g. silicon nitride), on the aforementioned structure, followed by etching back the deposited material by RIE. RIE may be performed in a direction substantially perpendicular to the substrate surface, so that the sacrificial gate 1029 may only remain within the recess of the channel nanosheet relative to the periphery of the hard mask. In this case, the above-mentioned recess may be substantially fully filled with the sacrificial gate 1029.

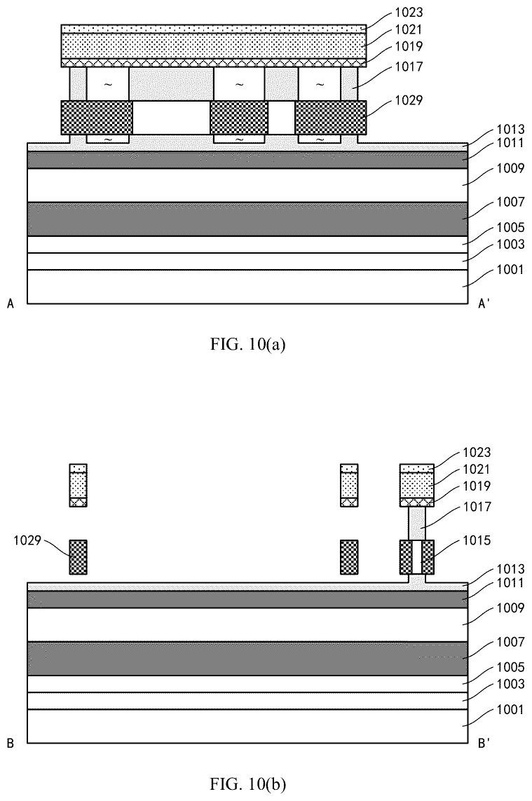

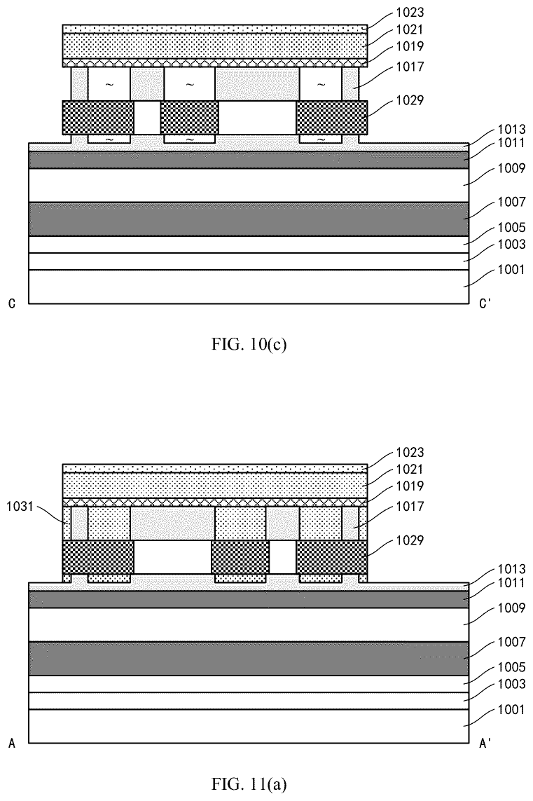

Similar to the treatment on the channel layer 1015, the second source/drain layer 1017 may be further selectively etched to be divided into several separate parts corresponding to the circular or rectangular parts of the mask pattern, as shown in FIGS. 10(a), 10(b), and 10(c) (which are the cross-sectional views along line AA′, line BB′, and line CC′ respectively). Except for different etching formulas, the selective etching of the second source/drain layer 1017 may be substantially the same as the selective etching of the channel layer 1015, which will not be repeated here. In addition, in this example, the first source/drain layer 1013, which has the same material as the second source/drain layer 1017, may also be affected by the etching formula, so as to form an undercut. Especially, a gap may be formed below the sacrificial gate 1029, which helps to reduce the capacitance between the gate and the source/drain.

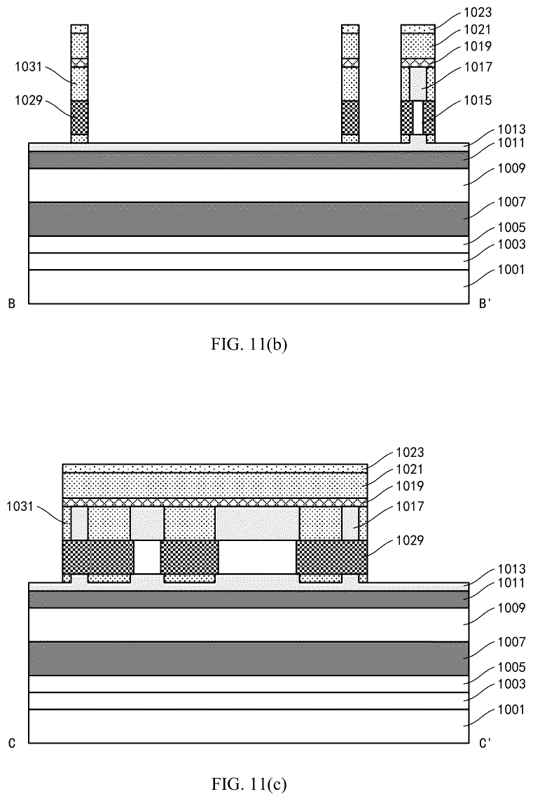

Similarly, an occupying layer may be formed in the gaps below the hard mask to avoid subsequent processing affecting the source/drain layer (for example, to avoid the gate stack forming in these gaps in the subsequent gate replacement process). For example, as shown in FIGS. 11(a), 11(b), and 11(c) (which are the cross-sectional views along line AA′, line BB′, and line CC′ respectively), an occupying layer 1031 may be formed by depositing materials with required etching selectivity (e.g., relative to the hard mask and the sacrificial gate 1029, etc.), such as nitride, on the aforementioned structure by chemical vapor deposition (CVD) or atomic layer deposition (ALD), followed by etching back the deposited material by RIE. Before etching back, planarization such as chemical mechanical polishing (CMP) (which may be stopped at the hard mask) may be performed on the deposited dielectric. RIE may be performed in a direction substantially perpendicular to the substrate surface, so that the occupying layer may only remain below the hard mask, and the outer sidewall of the occupying layer may be substantially coplanar with the outer sidewall of the hard mask. As shown in FIGS. 11(a) and 11(c), the occupying layer 1031 may be embedded in the undercut below the sacrificial gate 1029. Due to etching selectivity, the occupying layer 1031 may be left in the subsequent process of removing the sacrificial gate 1029 and replacing the sacrificial gate 1029 with the gate stack, thereby reducing the overlap between the gate stack and the source/drain layer and thus lowering the capacitance between the gate stack and the source/drain layer.

The active region of the p-type transistor may be defined in the lower layer according to a similar method.

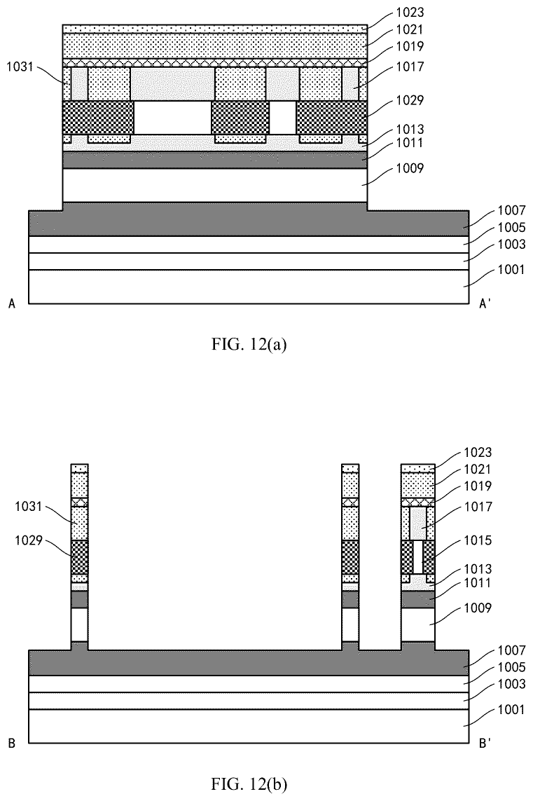

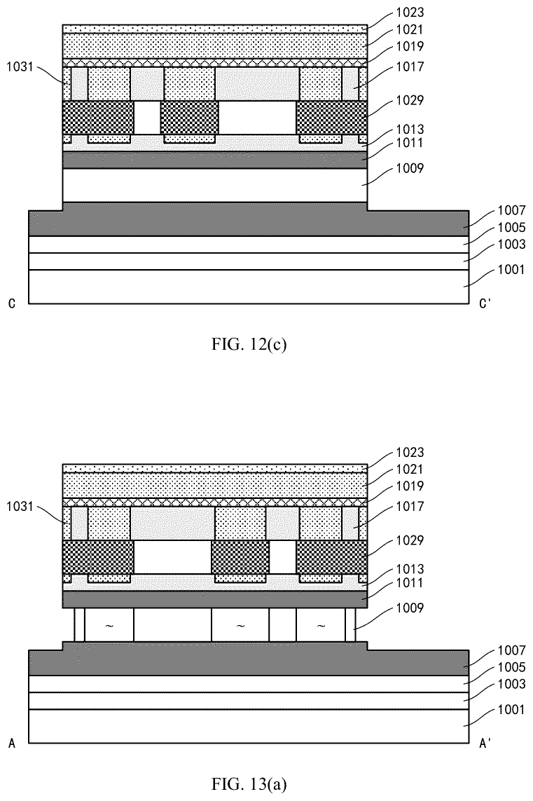

For example, as shown in FIGS. 12(a), 12(b), and 12(c) (which are the cross-sectional views along line AA′, line BB′, and line CC′ respectively), the hard mask may be used as an etching mask to sequentially etch the first source/drain layer 1013 for the n-type transistor, as well as the second source/drain layer 1011, the channel layer 1009, and the first source/drain layer 1007 for the p-type transistor, for example, by RIE. RIE may be performed in a direction substantially perpendicular to the substrate surface. Accordingly, the pattern of the hard mask may be transferred to these layers. In this example, RIE is performed to the first source/drain layer 1007, but not to the bottom of the first source/drain layer 1007. This is because in this example, the isolation auxiliary layer 1005 may include the same material, such as SiGe, as the channel layer 1009. Here, temporarily keeping the first source/drain layer 1007 covering the isolation auxiliary layer 1005 may help prevent affecting the isolation auxiliary layer 1005 when processing the channel layer 1009.

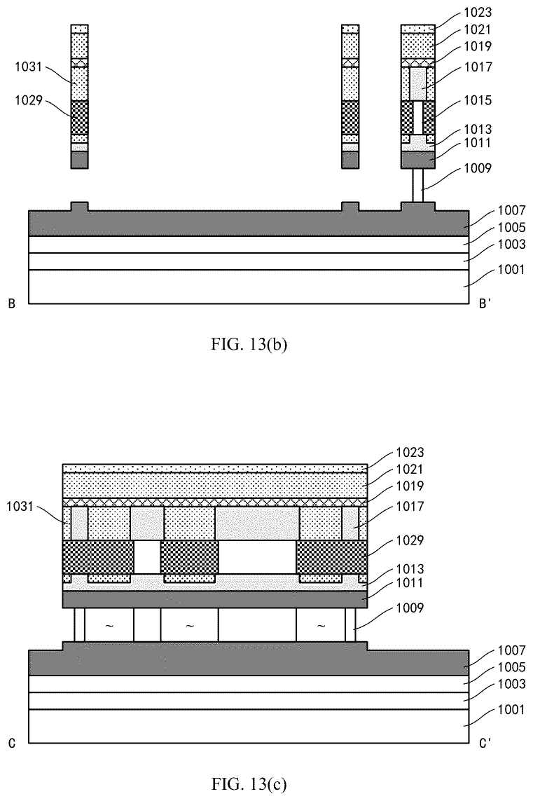

As shown in FIGS. 13(a), 13(b), and 13(c) (which are the cross-sectional views along line AA′, line BB′, and line CC′ respectively), selective etching, such as ALE, may be further performed on the channel layer 1009 to be divided into several separate parts corresponding to the circular or rectangular parts of the mask pattern, namely nanowires or nanosheets. For this, please refer to the description above in conjunction with FIGS. 7(a), 7(b), and 7(c). Compared to the channel layer 1015, although the same etching mask is used, the width of the nanosheets obtained in the channel layer 1009 may also be further adjusted by changing the etching conditions.

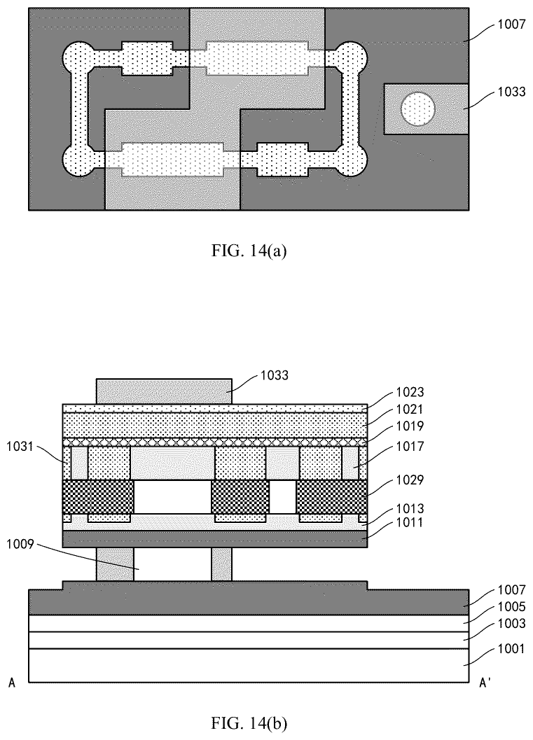

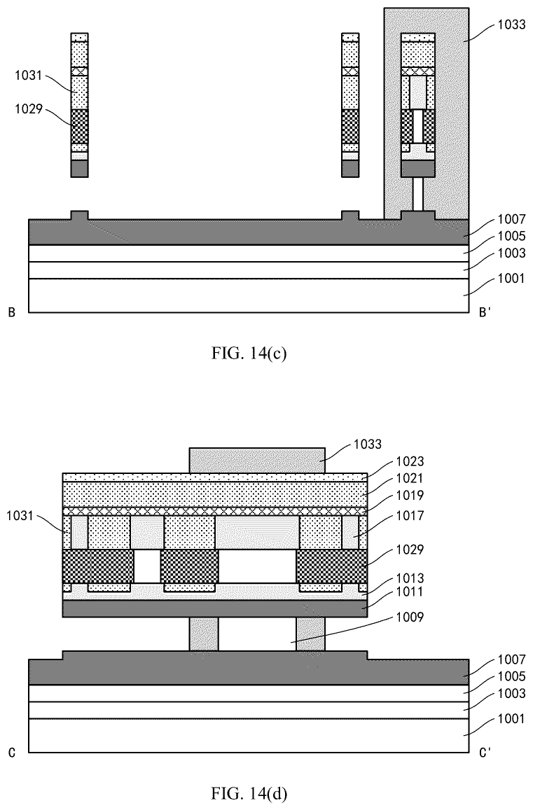

Similarly, at the positions corresponding to the circular parts MP_WL-1 and MP_WL-2 as well as the circular parts MP_V-1 and MP_V-2 in the mask pattern, the nanowires in the channel layer 1009 may be omitted. In addition, only two pull-up transistors PU1 and PU2 need to be formed in the lower layer, for example, the active regions of the pull-up transistors PU1 and PU2 are defined by the rectangular parts MP-PD/PU-1 and MP-PD/PU-2 in the mask pattern, respectively. Therefore, the nanosheets in the channel layer 1009 at positions corresponding to the rectangular parts MP-PG-1 and MP-PG-2 in the mask pattern, may also be omitted. As shown in FIGS. 14(a), 14(b), 14(c), and 14(d) (which are the top view and the cross-sectional views along line AA′, line BB′, and line CC′ respectively), a photoresist 1033 may be formed on the above structure and patterned to expose the nanowires and nanosheets in the channel layer that need to be removed. The photoresist 1033 may be used as an etching mask to selectively etch the exposed nanowires and nanosheets in the channel layer for removing the nanowires and nanosheets. Afterwards, the photoresist 1033 may be removed.

Similarly, the nanowire in the channel layer 1009 may be retained at a position corresponding to the circular part MP_V_{DD} in the mask pattern, to avoid the collapse of the material layer.

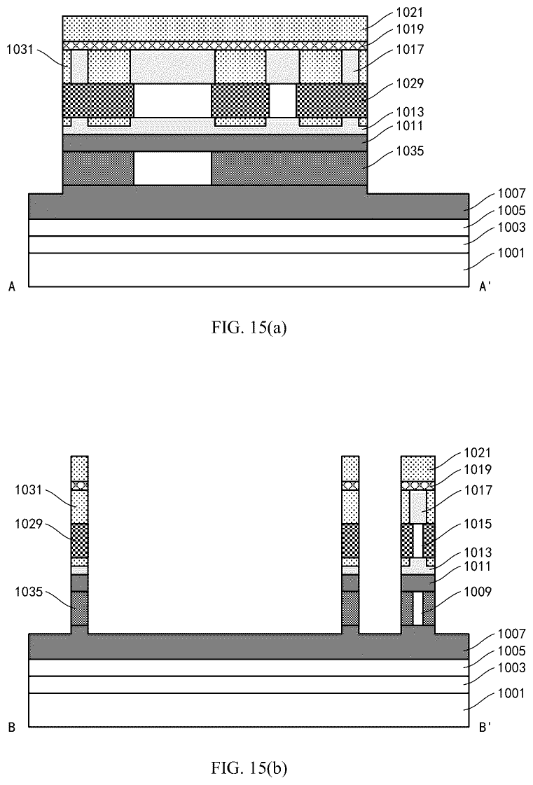

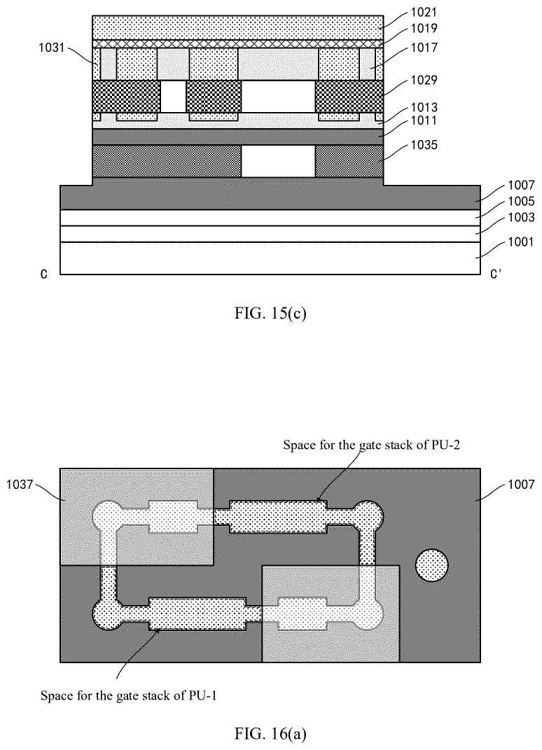

Similar to the upper layer, the sacrificial gate may also be formed around the channel layer 1009 (which has been patterned as separate nanosheets/nanowires). In addition, considering the electrical isolation between the gate stacks of the two p-type transistors in the lower layer, an occupying layer may be formed first. For example, as shown in FIGS. 15(a), 15(b), and 15(c) (which are the cross-sectional views along line AA′, line BB′, and line CC′ respectively), an occupying layer 1035 may be formed in the recess of each nanosheet/nanowire in the channel layer 1009 relative to the periphery of the hard mask. For example, the occupying layer 1035 may include materials with required etching selectivity (for example, relative to the sacrificial gate 1029 and the occupying layer 1031), such as oxide or low k dielectric. The occupying layer 1035 may be formed by deposition followed by etching back, similar to the process of forming the sacrificial gate 1029 or the occupying layer 1031. In the case where the occupying layer 1035 is oxide, the oxide layer 1023 in the hard mask may be removed during the etching back process.

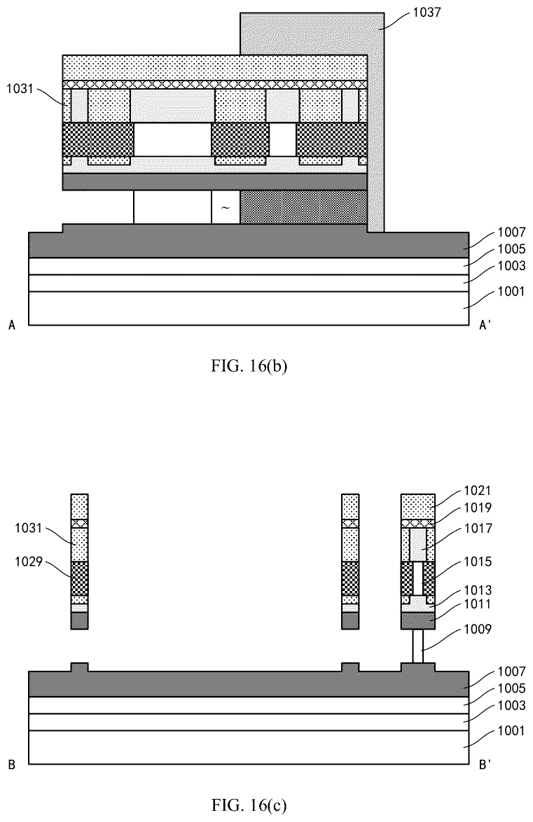

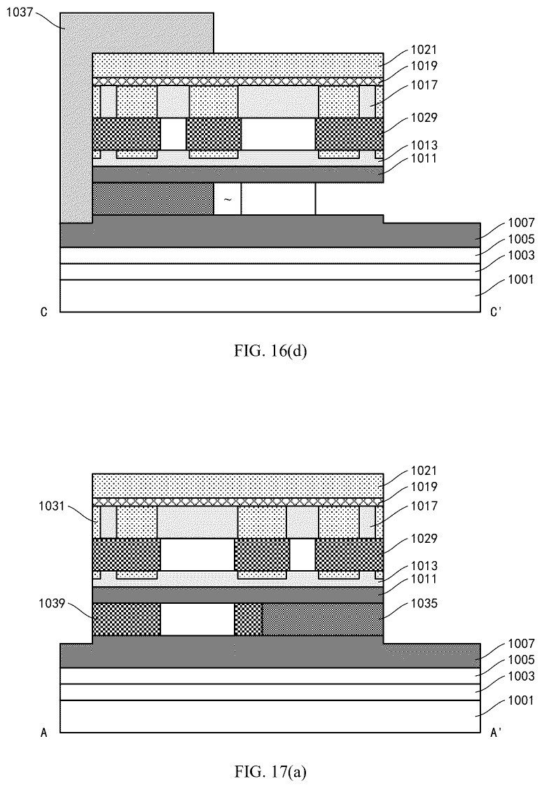

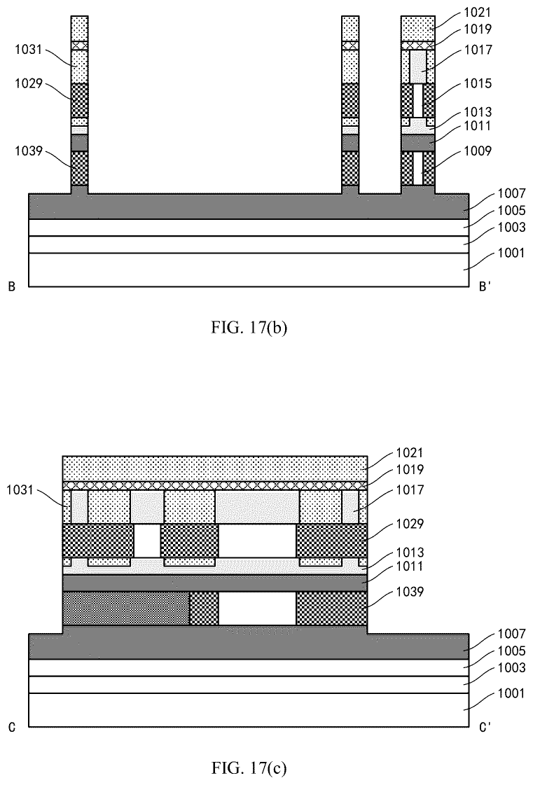

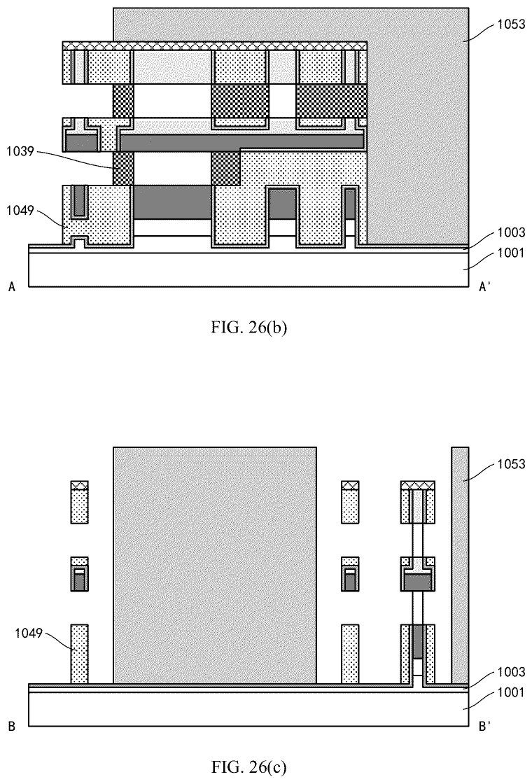

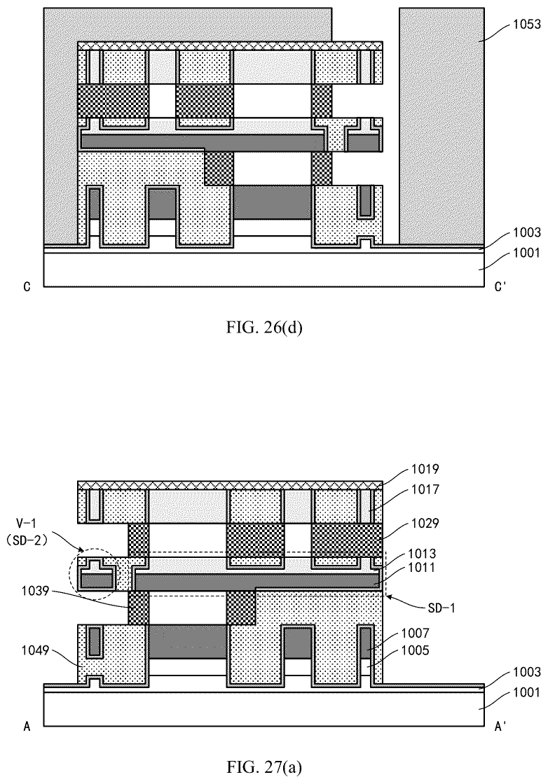

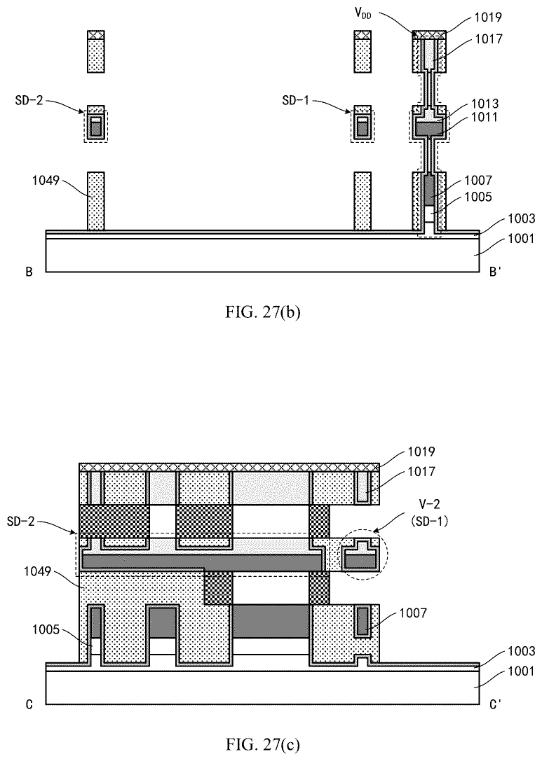

Next, the occupying layer 1035 may be patterned to leave the space for forming the gate stack of the p-type transistor. For example, as shown in FIGS. 16(a), 16(b), 16(c), and 16(d) (which are the top view and the cross-sectional views along line AA′, line BB′, and line CC′ respectively), a photoresist 1037 may be formed on the above structure and patterned to expose a region where the gate stack of the p-type transistor is needed to form. Specifically, in this example, as shown in the top view of FIG. 16(a), the space for forming the gate stack of the p-type transistor is left around the positions corresponding to the rectangular parts MP-PD/PU-1 and MP-PD/PU-2 (which respectively define positions of the channel portions of the pull-up transistors PU1 and PU2) in the mask pattern. In addition, in this example, the photoresist 1037 also exposes regions corresponding to the circular parts MP_V-1 and MP_V-2 in the mask pattern. This is because: the gate stack for the pull-up transistor PU1 may be extended to the region corresponding to the circular part MP_V-1 in the mask pattern to be electrically connected to the subsequently formed third interconnection structure V-1 at that region; and the gate stack for the pull-up transistor PU2 may be extended to the region corresponding to the circular part MP_V-2 in the mask pattern to be electrically connected to the fourth interconnection structure V-2 subsequently formed at that region. In addition, the photoresist 1037 may also expose the region corresponding to the circular part MP_V_{DD} in the mask pattern. In this way, in the region corresponding to the circular part MP_V_{DD} in the mask pattern, nanowires in the channel layers 1009 and 1015 are left, and the remaining nanowires may be surrounded by the sacrificial gate (see FIG. 17(b)). Subsequently, the remaining nanowires may be silicified to reduce resistance by removing the sacrificial gate in the same etching step (e.g., as described below in conjunction with FIGS. 26(a) to 27(c)). The photoresist 1037 may be used as an etching mask to selectively etch the occupying layer 1035.

Then, the sacrificial gate may be formed around the channel layer 1009 (which has been patterned as separate nanosheets/nanowires). For example, as shown in FIGS. 17(a), 17(b), and 17(c) (which are the cross-sectional views along line AA′, line BB′, and line CC′ respectively), a sacrificial gate 1039 may be formed in the recess (where the occupying layer 1035 has already been locally formed) of each nanosheet/nanowire in the channel layer 1009 relative to the outer periphery of the hard mask. The sacrificial gate 1039 may be formed by deposition followed by etching back, similar to the process of forming the sacrificial gate 1029. The sacrificial gate 1039 may include materials with required etching selectivity (for example, relative to the occupying layers 1031 and 1035), such as nitrogen oxide identical to the sacrificial gate 1029.

In the above example, the occupying layer 1035 is formed first, and then the sacrificial gate 1039 is formed. However, the present disclosure is not limited to this. For example, the sacrificial gate 1039 may also be formed first, and then the occupying layer 1035 is formed.

In addition, in this example, the sacrificial gate 1039 in the lower layer may be patterned before performing the gate replacement process on the sacrificial gate 1039 in the lower layer. This is because after the gate replacement process, it is not easy to pattern the gate stack in the lower layer. The sacrificial gate 1029 in the upper layer may be patterned after the gate replacement process, so as to achieve appropriate electrical isolation. Of course, similar to the sacrificial gate 1039 in the lower layer, the sacrificial gate 1029 in the upper layer may also be patterned before the gate replacement process. In this case, similar to the process of forming the sacrificial gate 1039 in the lower layer, an occupying layer may be formed before forming the sacrificial gate 1029, and the occupying layer may be patterned before forming the sacrificial gate 1029.

Next, the source/drain layer in the lower layer may be separated similarly.

It should be noted that, in this example, it is not necessary to divide the first source/drain layer 1013 of the n-type transistor and the second source/drain layer 1011 of the p-type transistor into separate parts for the transistors, as they may then be used to form the first and second interconnection structures as well as the third and fourth interconnection structures.

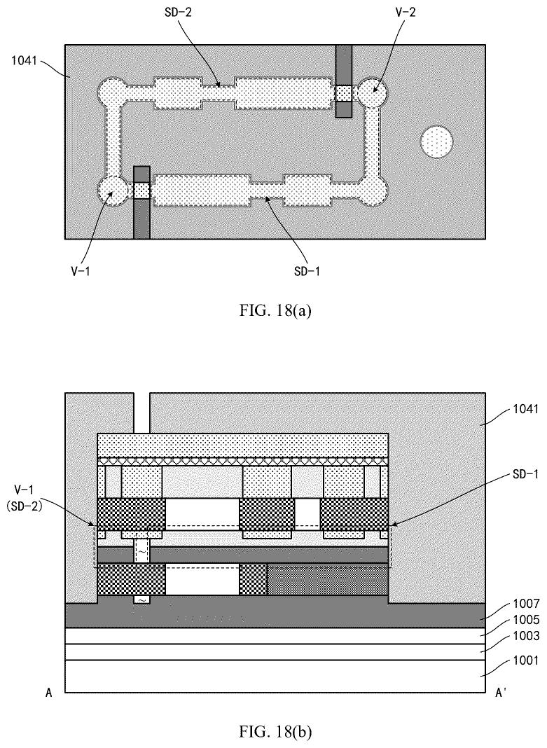

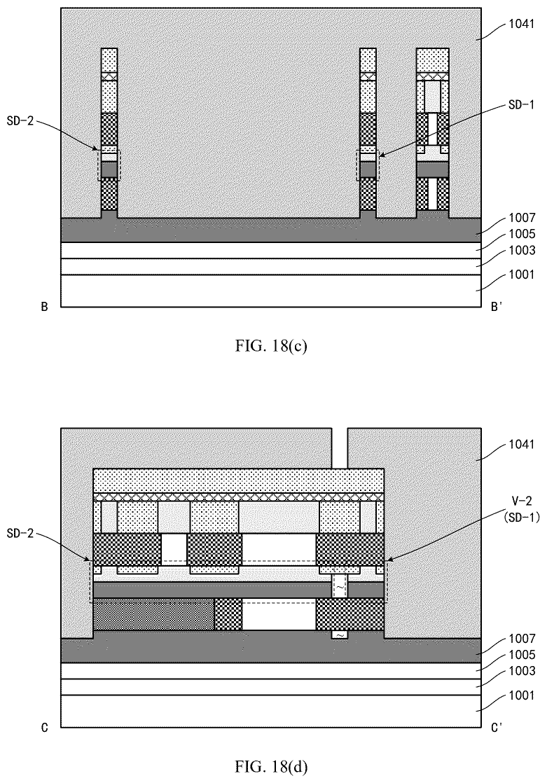

The first source/drain layer 1013 for the n-type transistor and the second source/drain layer 1011 for the p-type transistor may be patterned according to the arrangement of the first and second interconnection structures, as well as the third and fourth interconnection structures. For example, as shown in FIGS. 18(a), 18(b), 18(c), and 18(d) (which are the top view and the cross-sectional views along line AA′, line BB′, and line CC′ respectively), a photoresist 1041 may be formed on the above structure. The photoresist 1041 may be patterned to expose the region that needs to be isolated between the first interconnection structure and the second interconnection structure. Then, the photoresist 1041 may be used as the etching mask to selectively etch the first source/drain layer 1013 for the n-type transistor and the second source/drain layer 1011 for the p-type transistor by ALE, to cut them off. Accordingly, in the top view, the first source/drain layer 1013 for the n-type transistor and the second source/drain layer 1011 for the p-type transistor may be formed as two opposite L-shaped structures spaced from each other (so as to obtain the first interconnection structure SD-1 and the second interconnection structure SD-2, as shown by the dashed line in FIG. 18(a)). The first source/drain layer 1007 for the p-type transistor may also be affected by etching, so as to form an undercut.

As shown, the first interconnection structure SD-1 may include a first segment (see the top view in FIG. 18(a) and a dashed box on the right side of the cross-sectional view of FIG. 18(b)) extending along the first direction, as well as a second segment (see the top view in FIG. 18(a) and a dashed box on the right side of the cross-sectional view of FIG. 18(c)) extending along the second direction. The fourth interconnection structure V-2 (see the top view in FIG. 18(a), and a dashed box on the right side of the cross-sectional view in FIG. 18(d)) may be obtained at a position corresponding to the circular part MP_V-2 in the mask pattern. The fourth interconnection structure V-2 may be integrated with the first interconnection structure SD-1 (both defined by continuously extending source/drain layers 1011 and 1013). Similarly, the second interconnection structure SD-2 may include a third segment (see the top view in FIG. 18(a) and a dashed box on the left side of the cross-sectional view in FIG. 18(d)) extending along the first direction, as well as a fourth segment (see the top view in FIG. 18(a) and a dashed box on the left side of the cross-sectional view in FIG. 18(c)) extending along the second direction. The third interconnection structure V-1 (see the top view in FIG. 18(a) and the dashed box on the left side of the cross-sectional view in FIG. 18(b)) may be obtained at a position corresponding to the circular part MP_V-1 in the mask pattern. The third interconnection structure V-1 may be integrated with the second interconnection structure SD-2 (both defined by continuously extending source/drain layers 1011 and 1013).

The first interconnection structure SD-1, particularly a part of the first interconnection structure SD-1 located below the corresponding nanosheets in the channel layer 1015, may be used as the source/drain portions of the first pull-down transistor PD-1 and the first pass-gate transistor PG-1. The first interconnection structure SD-1, especially a part of the first interconnection structure SD-1 located above the corresponding nanosheets in the channel layer 1009, may be used as the source/drain portion of the first pull-up transistor PU-1 (therefore, the source/drain portions of the first pull-down transistor PD-1, the first pass-gate transistor PG-1, and the first pull-up transistor PU-1 are electrically connected to each other through the first interconnection structure SD-1). Similarly, the second interconnection structure SD-2, particularly a part of the second interconnection structure SD-2 located below the corresponding nanosheets in the channel layer 1015, may be used as the source/drain portions of the second pull-down transistor PD-2 and the second pass-gate transistor PG-2. The second interconnection structure SD-2, especially a part of the second interconnection structure SD-2 located above the corresponding nanosheets in the channel layer 1009, may be used as the source/drain portion of the second pull-up transistor PU-2 (therefore, the source/drain portions of the second pull-down transistor PD-2, the second pass-gate transistor PG-2, and the second pull-up transistor PU-2 are electrically connected to each other through the second interconnection structure SD-2). Such source/drain portions are self-aligned with the corresponding channel nanosheets.

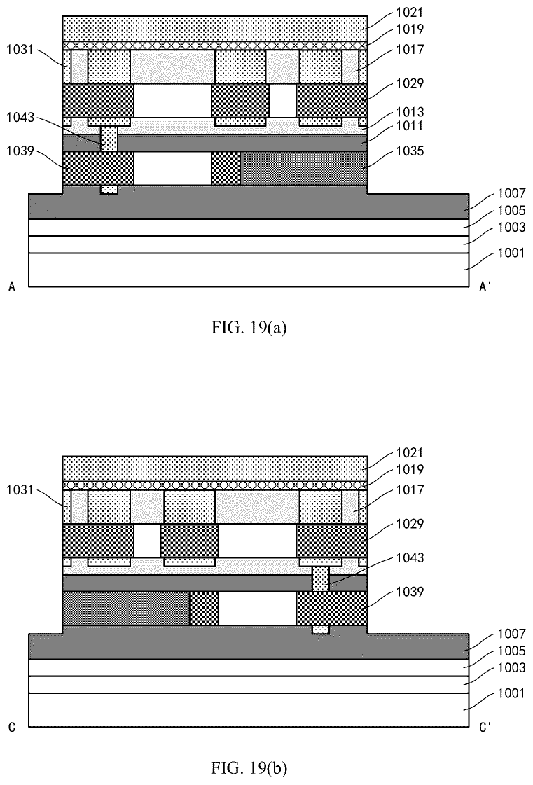

An occupying layer may be formed in the gap formed below the hard mask due to the aforementioned etching. For example, as shown in FIGS. 19(a) and 19(b) (which are the cross-sectional views along line AA′ and line CC′ respectively), an occupying layer 1043 may be formed by deposition followed by etching back. The occupying layer 1043 may include materials with desired etching selectivity (for example, relative to the sacrificial gates 1029 and 1039), such as nitride. The occupying layer 1043 and the occupying layer 1031 may include the same material.

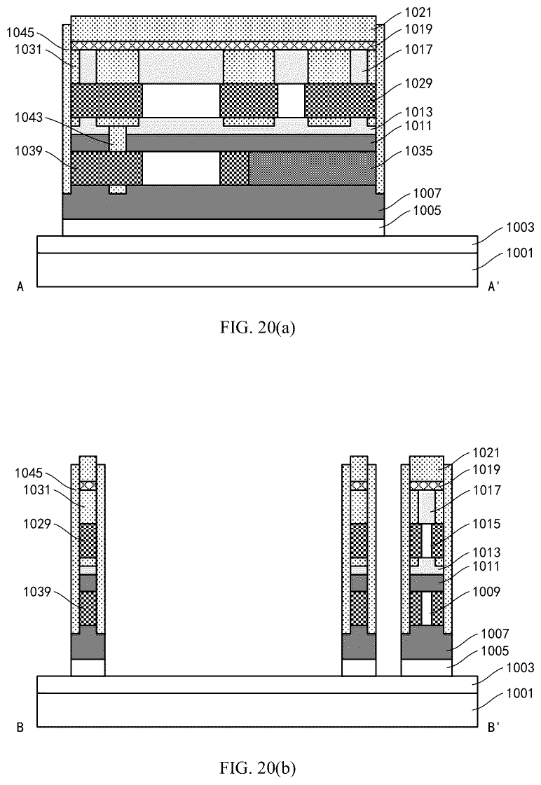

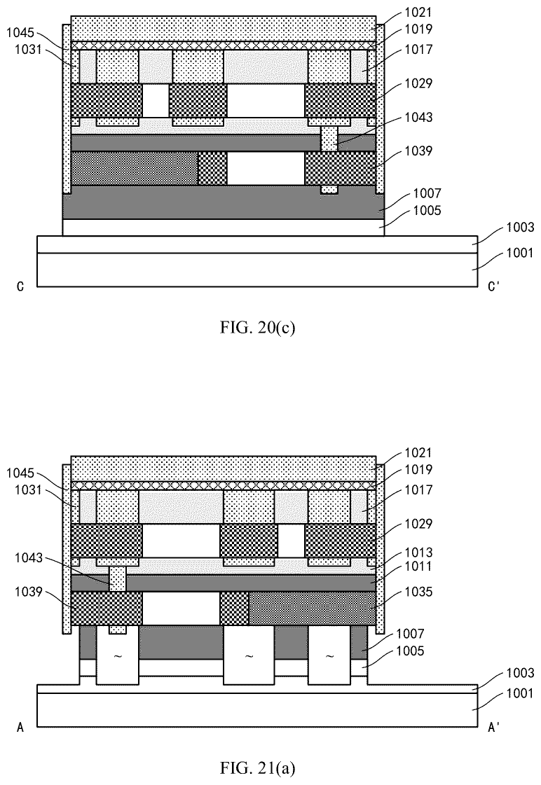

In addition, in order to avoid affecting the first source/drain layer 1013 for the n-type transistor and the second source/drain layer 1011 for the p-type transistor in the process of separating the first source/drain layer 1007 for the p-type transistor, a protective layer may be formed on the sidewall of the above structure. For example, as shown in FIGS. 20(a), 20(b), and 20(c) (which are the cross-sectional views along line AA′, line BB′, and line CC′ respectively), a protective layer 1045 may be formed on the sidewall of the above structure through the spacer formation process. The protective layer 1045 may include materials with required etching selectivity (relative to the first source/drain layer 1007), such as nitride. The spacer formation process may include forming a nitride thin layer on the above-mentioned structure in a substantially conformal manner, and anisotropic etching of the deposited nitride thin layer by RIE in the vertical direction to remove a lateral extension part of the nitride thin layer and leave a vertical extension part of the nitride thin layer.

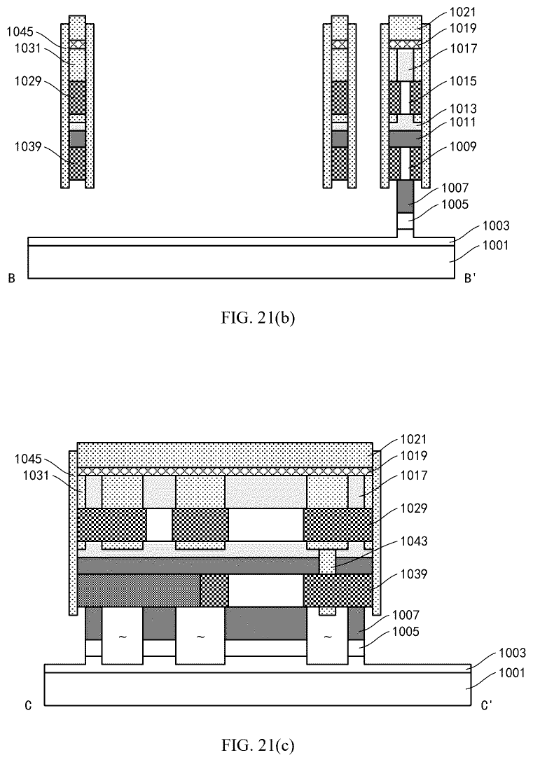

Afterwards, the first source/drain layer 1007 may be separated. Such separation may be the same as the above separation. For example, a hard mask may be used as the etching mask to selectively etch the first source/drain layer 1007 by, such as RIE in the vertical direction. The RIE of the first source/drain layer 1007 may be stopped at the isolation auxiliary layer 1005. In this way, the pattern of the hard mask is transferred to the first source/drain layer 1007. Then, as shown in FIGS. 21(a), 21(b), and 21(c) (which are the cross-sectional views along line AA′, line BB′, and line CC′ respectively), the first source/drain layer 1007 may be further selectively etched by, such as ALE, to divide it into several separate parts corresponding to the circular or rectangular parts of the mask pattern, namely nanowires or nanosheets. To ensure proper electrical isolation, it is desired that the first source/drain layer 1007 be completely divided into several separate parts or nanowires. The sidewalls of the first source/drain layer 1013 for the n-type transistor and the second source/drain layer 1011 for the p-type transistor, which are also Si, may be basically unaffected by such etching, because they are surrounded by the protective layer 1045, thereby maintaining the patterns of the first and second interconnection structures.

At this point, the active region of each transistor has been basically defined.

In addition, the same separation may be performed on the isolation auxiliary layer 1005 to divide the isolation auxiliary layer 1005 into separate parts. For example, in the process described above in conjunction with FIGS. 20(a), 20(b), and 20(c), after selectively etching the first source/drain layer 1007, the isolation auxiliary layer 1005 may be further selectively etched to transfer the pattern of the hard mask to the isolation auxiliary layer 1005. Then, in the process described above in conjunction with FIGS. 21(a), 21(b), and 21(c), the isolation auxiliary layer 1005 may be further selectively etched to be divided. By dividing the isolation auxiliary layer 1005 into parts corresponding to the circular or rectangular parts of the mask pattern, the first source/drain layer 1007 may be separated from the contact layer 1003 below at a desired position (specifically, the position where the third and fourth interconnection structures are located), and the isolation between the third and fourth interconnection structures (connected to the gate stack of the p-type transistor) and the contact layer 1003 (in electrical contact with the lower source/drain region of the p-type transistor) may be facilitated. An undercut may be formed in the contact layer 1003.

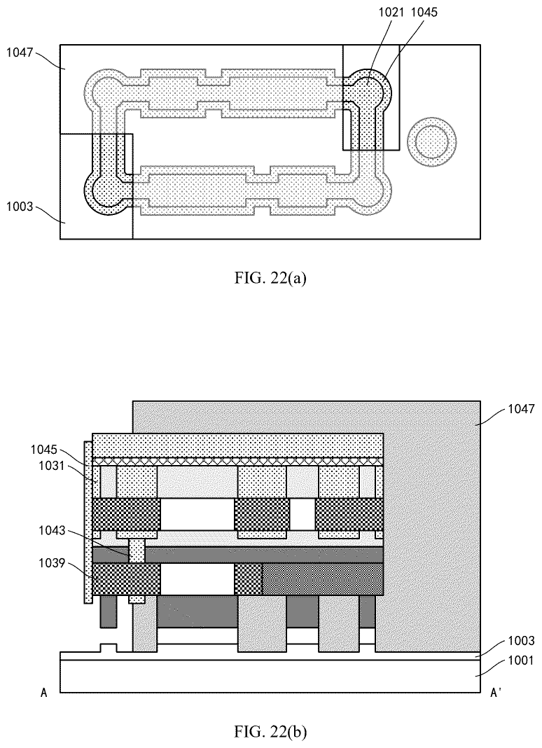

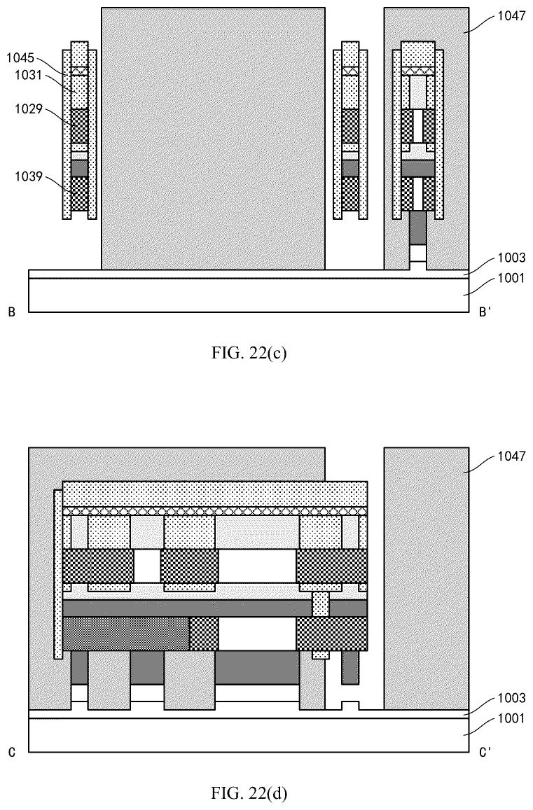

For example, as shown in FIGS. 22(a), 22(b), 22(c), and 22(d) (which are the top view and the cross-sectional views along line AA′, line BB′, and line CC′ respectively), a photoresist 1047 may be formed on the above structure. The photoresist 1047 may be patterned to expose a region where the third and fourth interconnection structures are located. Then, the photoresist 1047 may be used as the etching mask to selectively etch the isolation auxiliary layer 1005, so as to remove the exposed part of the isolation auxiliary layer 1005. Accordingly, at the position where the third and fourth interconnection structures are located, the first source/drain layer 1007 may be separated from the contact layer 1003. Selective etching may be further performed on the first source/drain layer 1007 and the contact layer 1003 (both Si in this example) to increase the gap between the first source/drain layer 1007 and the contact layer 1003, ensuring good electrical isolation performance and reducing capacitance. Afterwards, the photoresist 1047 may be removed.

In this example, the separation between the first source/drain layer 1007 and the contact layer 1003 may be achieved by using the isolation auxiliary layer 1005. However, the present disclosure is not limited to this. According to other embodiments of the present disclosure, the isolation auxiliary layer 1005 may be omitted. In this case, for example, a photoresist may be formed on the structures (without the isolation auxiliary layer 1005) shown in FIGS. 21(a), 21(b), 21(c), and 21(d), which may have the same pattern as the photoresist 1047. Then, the photoresist may be used as an etching mask to selectively etch the first source/drain layer 1007 to remove the exposed part of the first source/drain layer 1007. Accordingly, the first source/drain layer 1007 is removed at the position where the third and fourth interconnection structures are located. Afterwards, the photoresist may be removed.

Hereinafter, the case where the isolation auxiliary layer 1005 exists is still used as an example for description.

At this point, the arrangement definition for SRAM cells (including transistors and interconnection structures) has been basically completed. Next, the gate replacement process may be performed to complete the fabrication of transistors, and interconnections between these transistors may be formed to complete the fabrication of SRAM cells.

To enhance the contact and/or reduce resistance, the source/drain layer may be silicified.

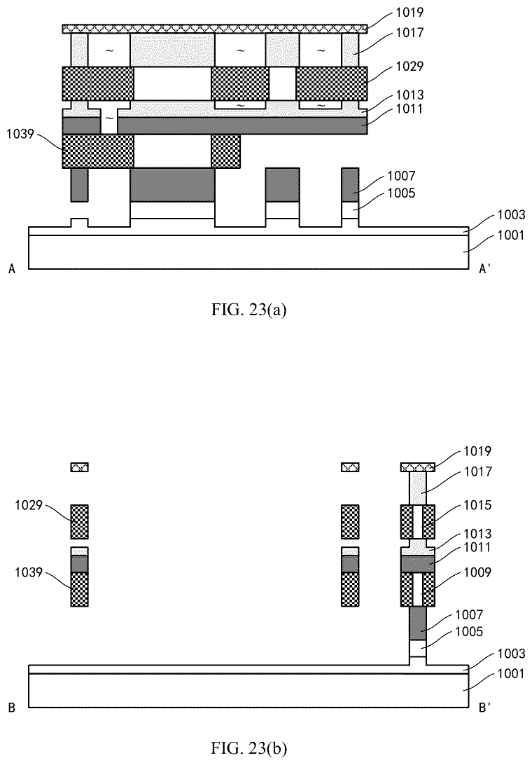

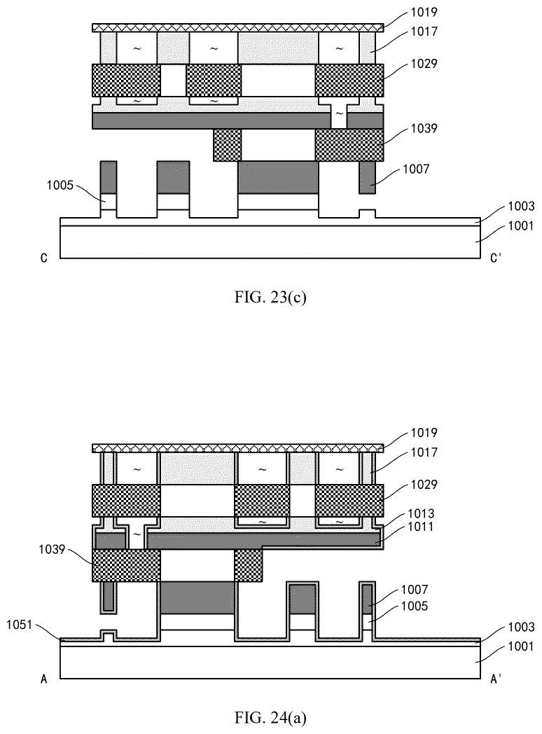

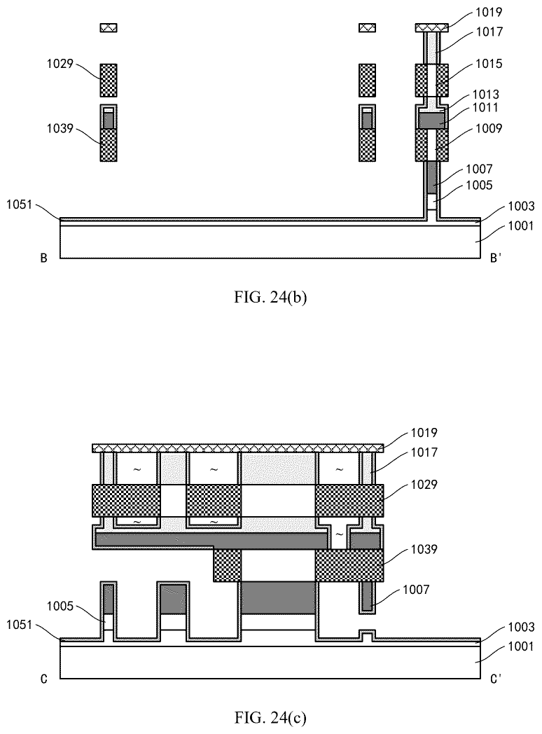

As shown in FIGS. 23(a), 23(b), and 23(c) (which are the cross-sectional views along line AA′, line BB′, and line CC′ respectively), the occupying layers 1031, 1043 (nitride), and 1035 (oxide or low k dielectric) may be removed by selective etching, such as wet etching with hot phosphoric acid, relative to the sacrificial gates 1029 and 1039 (as well as the aluminum oxide layer 1019 in the hard mask). During the selective etching process, the nitride layer 1021 in the hard mask and the nitride protective layer 1045 may also be removed. Accordingly, the sidewall of each source/drain layer may be at least partially exposed, while the sidewall of the channel layer is surrounded by the sacrificial gates 1029 and 1039. The silicification may be performed to at least partially or completely silicify the exposed source/drain layers, so as to form a silicide layer 1051, as shown in FIGS. 24(a), 24(b), and 24(c) (which are the cross-sectional views along line AA′, line BB′, and line CC′ respectively). The silicification may include depositing metals such as NiPt alloys and heating at a temperature in a range of 200° C. to 600° C. to allow the deposited metal to react with semiconductor elements such as Si and/or Ge in the source/drain layer, so as to form compounds of metal and semiconductor elements, such as silicide, germanide, or siliconide (hereinafter referred to as silicide). Afterwards, the unreacted excess metal may be removed.

It should be noted that although the silicide layer 1051 is shown as a thin layer here, certain parts (such as those in the source/drain layer that correspond to the circular part of the mask pattern) may be completely converted into silicide according to the size of the part where the silicification reaction occurs and the time of the silicification reaction.

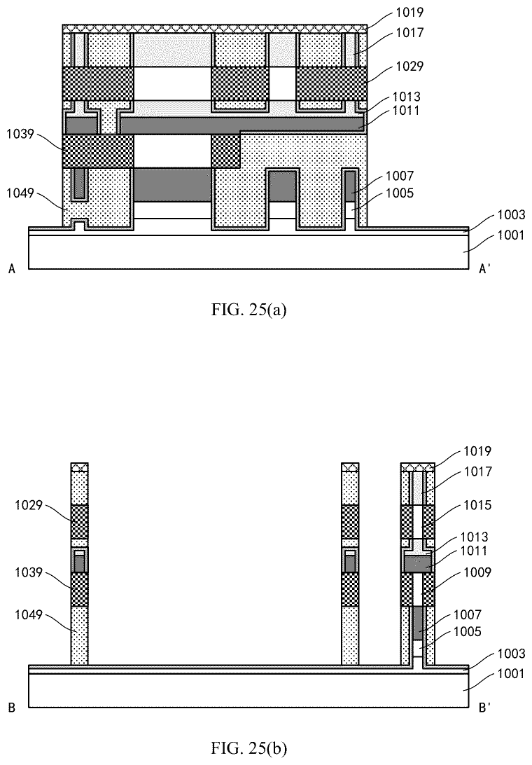

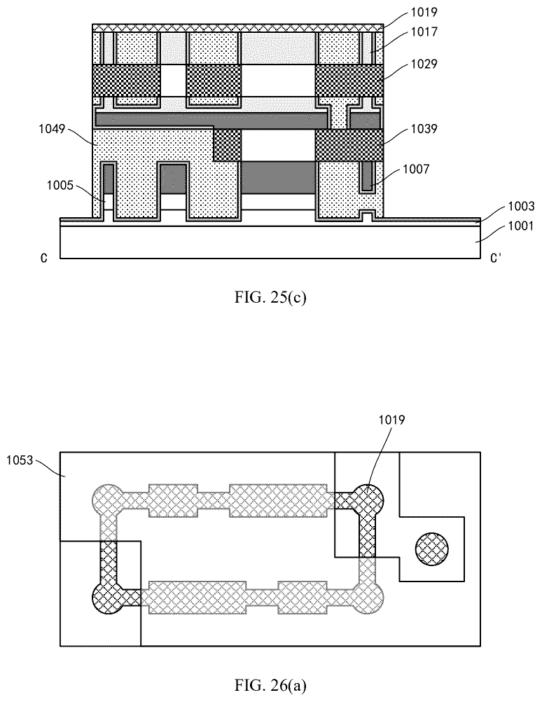

Next, as shown in FIGS. 25(a), 25(b), and 25(c) (which are the cross-sectional views along line AA′, line BB′, and line CC′ respectively), an occupying layer 1049 may be reformed in the gap below the hard mask (currently only including the aluminum oxide layer 1019). As mentioned above, the occupying layer 1049 may be formed by deposition followed by etching back. The occupying layer 1049 may include materials with desired etching selectivity (for example, relative to the sacrificial gates 1029 and 1039 as well as the hard mask), such as nitride.

At the positions of the third interconnection structure, the fourth interconnection structure, and the contact plug used to apply the power supply voltage V_{DD}, the silicification may be performed on the existing nanowires to reduce resistance.

For example, as shown in FIGS. 26(a), 26(b), 26(c), and 26(d) (which are the top view and the cross-sectional views along line AA′, line BB′, and line CC′ respectively), a photoresist 1053 may be formed on the above structure. The photoresist 1053 may be patterned to expose a region where the third and fourth interconnection structures are located, as well as a region where the contact plug for applying the power supply voltage V_{DD} is located. The photoresist 1053 may be used as an etching mask to selectively etch the sacrificial gates 1029 and 1039 (relative to the occupying layer 1049 and various channel layers and source/drain layers), so as to expose the nanowires that require silicification.

Then, as shown in FIGS. 27(a), 27(b), and 27(c) (which are the cross-sectional views along line AA′, line BB′, and line CC′ respectively), the silicification may be performed on the exposed channel layer nanowires to form silicide (which is shown integrated with the previous silicide 1051). The silicification may be performed as described above.

Accordingly, the contact plug for applying the power supply voltage V_{DD} may be formed. Specifically, as shown in FIG. 27(b), at the position where the contact plug used to apply the power supply voltage V_{DD} is located, the silicide layer (note that at this point, various channel layers and source/drain layers may have been completely silicified) extends continuously to the contact layer 1003 below the aluminum oxide layer 1019 in the hard mask layer.

In addition, the silicon oxide layer is also formed on the (at least a part of) surfaces of the first interconnection structure SD-1, the second interconnection structure SD-2, the third interconnection structure V-1, and the fourth interconnection structure V-2. The third interconnection structure V-1 and the fourth interconnection structure V-2 extend between the gate stack space in the upper layer and the gate stack space in the lower layer respectively, so that the subsequently formed gate stack (of the pull-down transistor) in the upper layer and the gate stack (of the pull-up transistor) in the lower layer are electrically connected to each other.

Next, the gate replacement process may be performed.

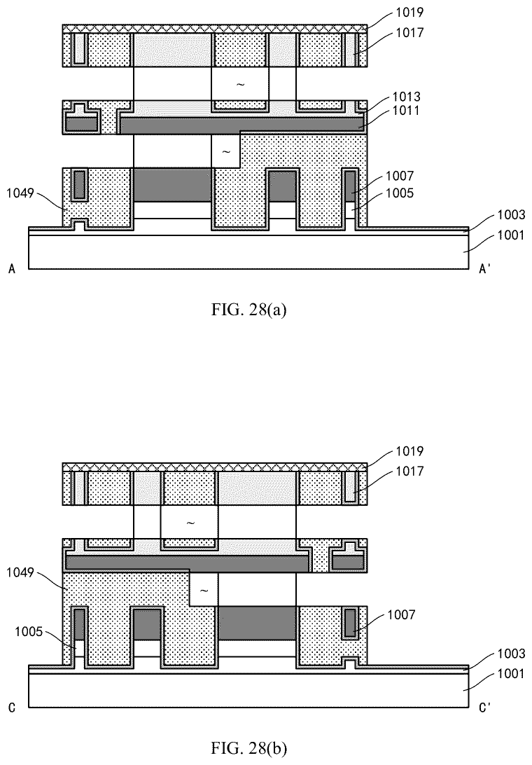

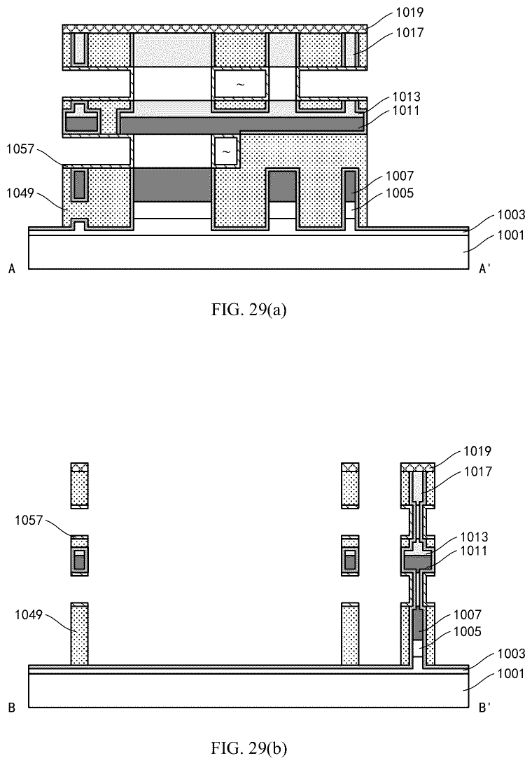

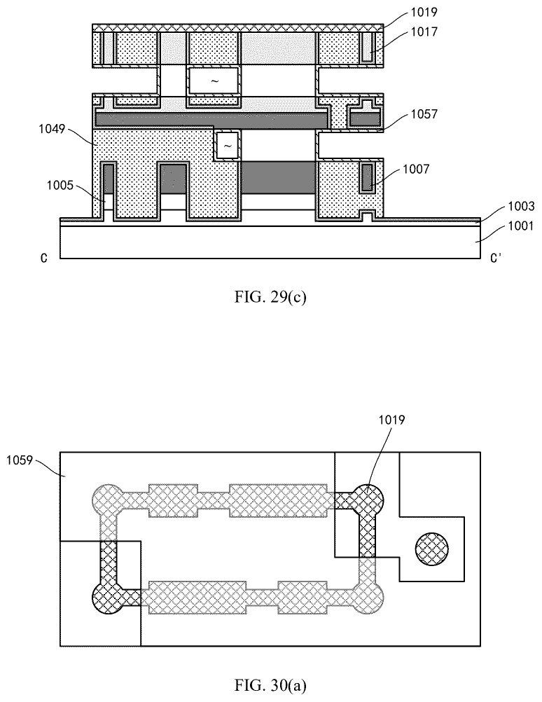

For example, as shown in FIGS. 28(a) and 28(b) (which are the cross-sectional views along line AA′ and line CC′ respectively), the sacrificial gates 1029 and 1039 may be removed by selective etching (relative to the aluminum oxide layer 1019, the occupying layer 1049, and each channel layer and source/drain layer or silicide formed therein). Accordingly, the sidewall of each nanosheet in the channel layer may be at least partially exposed. Next, as shown in FIGS. 29(a), 29(b), and 29(c) (which are the cross-sectional views along line AA′, line BB′, and line CC′ respectively), a gate dielectric layer 1057 may be formed on the sidewall of each nanosheet in the channel layer by deposition, such as atomic layer deposition (ALD). The gate dielectric layer 1057 may be formed in a substantially conformal manner. The gate dielectric layer 1057 may include suitable dielectrics, such as high k dielectrics such as HfO₂, with a thickness in a range of 0.5 nm to 4 nm.

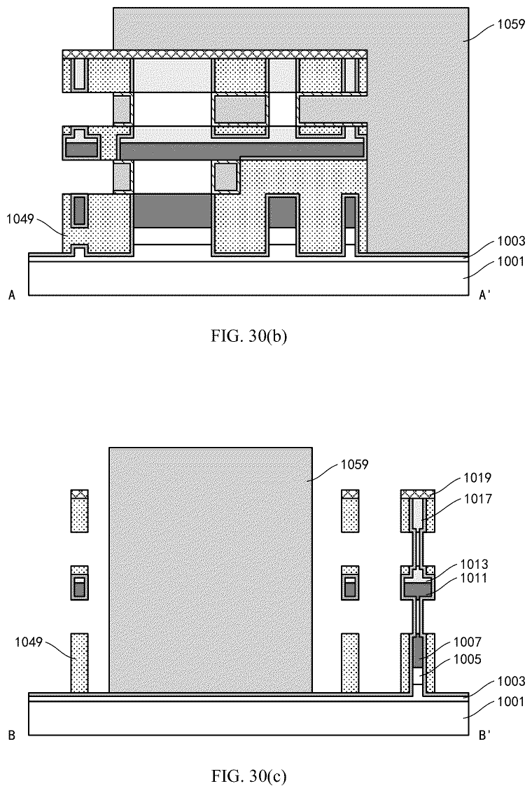

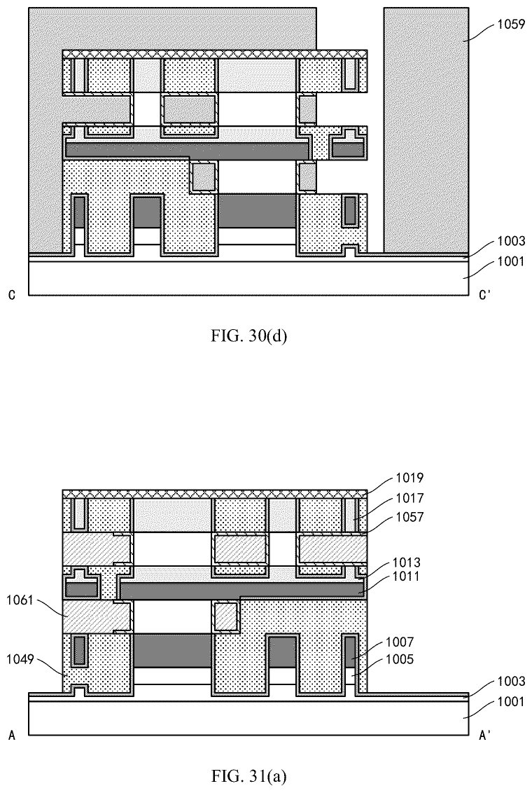

However, as a result, a gate dielectric layer is also formed on the surfaces of the third and fourth interconnection structures, which hinders the electrical connection between the third and fourth interconnection structures and the subsequently formed gate electrode layer. To this end, the gate dielectric layer on the surfaces of the third and fourth interconnection structures (and optionally the contact plug used for applying the power supply voltage V_{DD}) may be removed. As shown in FIGS. 30(a), 30(b), 30(c), and 30(d) (which are the top view and the cross-sectional views along line AA′, line BB′, and line CC′ respectively), a photoresist 1059 may be formed on the above structure. The photoresist 1059 may be patterned to expose the region where the third and fourth interconnection structures (and optionally the contact plug used for applying the power supply voltage V_{DD}) are located. The photoresist 1059 may be used as an etching mask to selectively etch the gate dielectric layer 1057 (relative to the occupying layer 1049 and silicide), so as to remove the exposed part of the gate dielectric layer 1057. Afterwards, the photoresist 1059 may be removed.

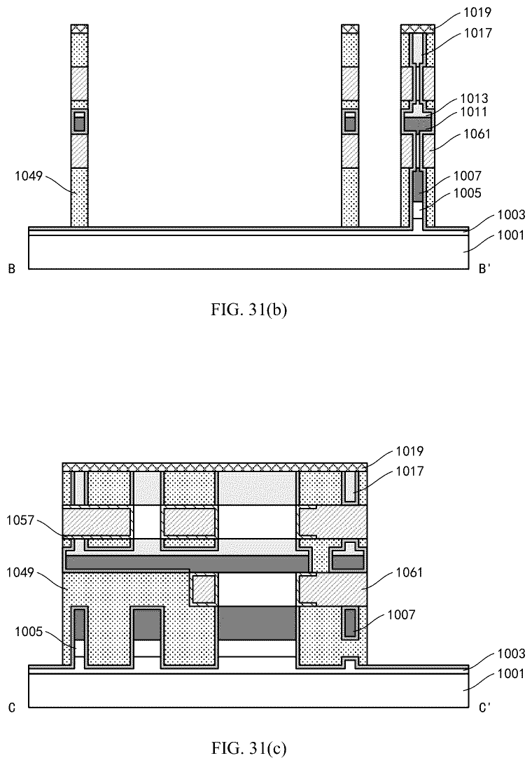

Then, as shown in FIGS. 31(a), 31(b), and 31(c) (which are the cross-sectional views along line AA′, line BB′, and line CC′ respectively), a gate electrode layer 1061 may be formed in the gap below the aluminum oxide layer 1019 through deposition followed by etching back. For example, the gate electrode layer 1061 may include a work function layer and a conductive filling layer. For example, for the p-type transistor, the work function layer may include TiN, TaN, or a combination thereof, with a thickness in a range of 1 nm to 7 nm. The conductive filling layer may include W and/or Ti, with a thickness sufficient to fill the gap below the hard mask. As shown in FIG. 31(a), the gate electrodes of the p-type pull-up transistor and the n-type pull-down transistor in the first group may be electrically connected to each other through the third interconnection structure. Similarly, as shown in FIG. 31(c), the gate electrodes of the p-type pull-up transistor and the n-type pull-down transistor in the second group may be electrically connected to each other through the fourth interconnection structure.

To further improve performance, different gate electrode layers, such as gate electrode layers with different effective work functions, may be formed for the p-type transistor and the n-type transistor respectively. For example, the gate electrode layer 1061 formed above, especially the work function layer therein, may be specific to the p-type transistor. Next, a gate electrode layer may be formed for the n-type transistor in the upper layer. For example, the gate electrode layer 1061 formed in the upper layer may be removed, and a gate electrode layer for the n-type transistor may be additionally formed.

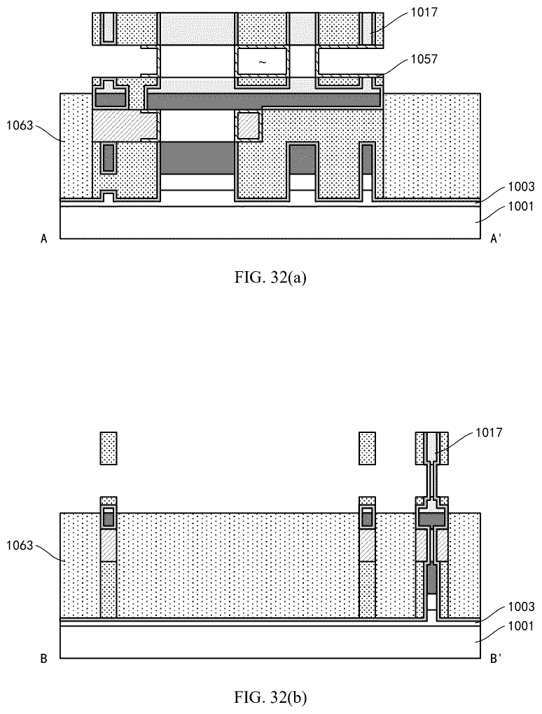

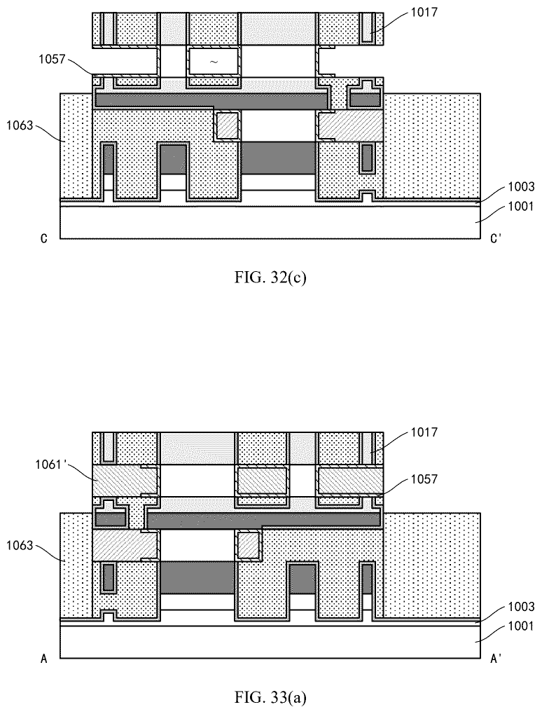

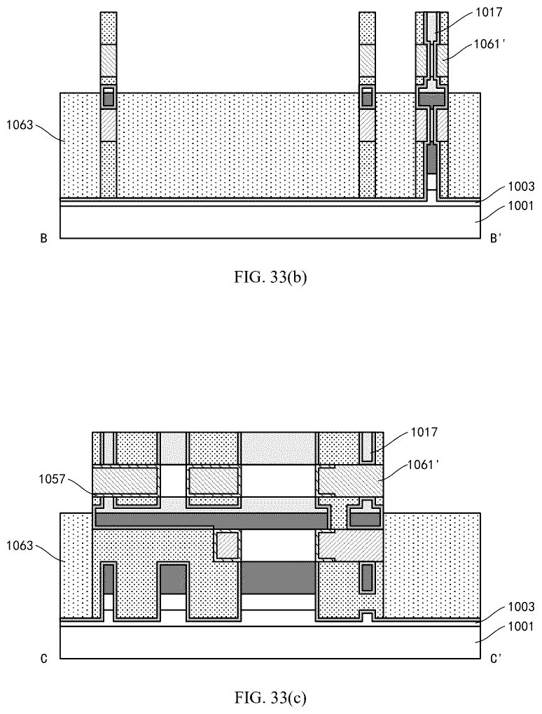

To avoid affecting the gate electrode layer 1061 in the lower layer, the gate electrode layer 1061 in the lower layer may be shielded. For example, as shown in FIGS. 32(a), 32(b), and 32(c) (which are the cross-sectional views along line AA′, line BB′, and line CC′ respectively), a shielding layer 1063 may be formed on the above structure through deposition followed by etching back. The shielding layer 1063 may also serve as an electrical isolation, and thus may include dielectric materials with required etching selectivity (for example, relative to the gate electrode layer 1061), such as oxide. Before etching back, planarization such as CMP may be performed on the deposited material. To fully shield the lower layer and expose the upper layer, the top surface of the shielding layer 1063 after etching back may be located between the upper and lower layers, such as at or near the interface between the first source/drain layer 1013 for the n-type transistor and the second source/drain layer 1011 for the p-type transistor. In addition, during the etching back process, the aluminum oxide layer 1019 may also be removed. Afterwards, the gate electrode layer 1061 in the upper layer may be removed by selective etching, and a gate electrode layer 1061′ for the n-type transistor may be formed in the upper layer in the same way as forming the gate electrode layer 1061, as shown in FIGS. 33(a), 33(b), and 33(c) (which are the cross-sectional views along line AA′, line BB′, and line CC′ respectively). For example, the gate electrode layer 1061′ may include a work function layer and a conductive filling layer. For example, for the n-type transistor, the work function layer may include TIN, TiNa, TiAlC or any combination thereof, with a thickness in a range of 1 nm to 7 nm; and the conductive filling layer may include W and/or Ti, with a thickness sufficient to fill the gap below the hard mask.

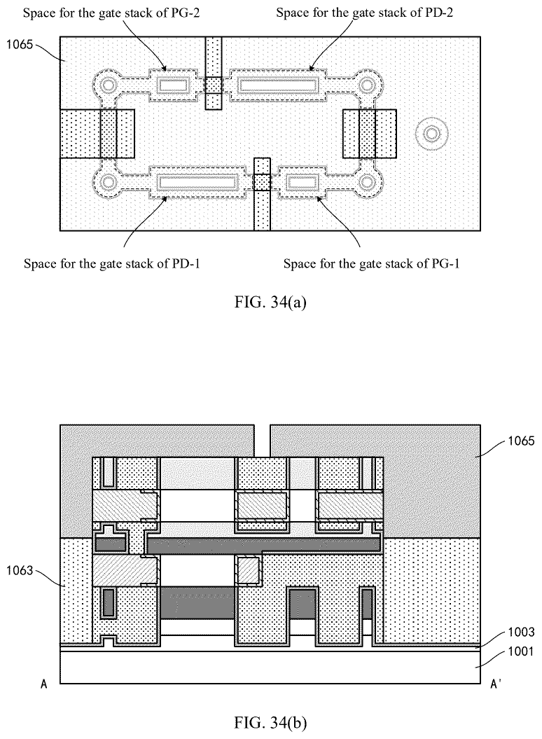

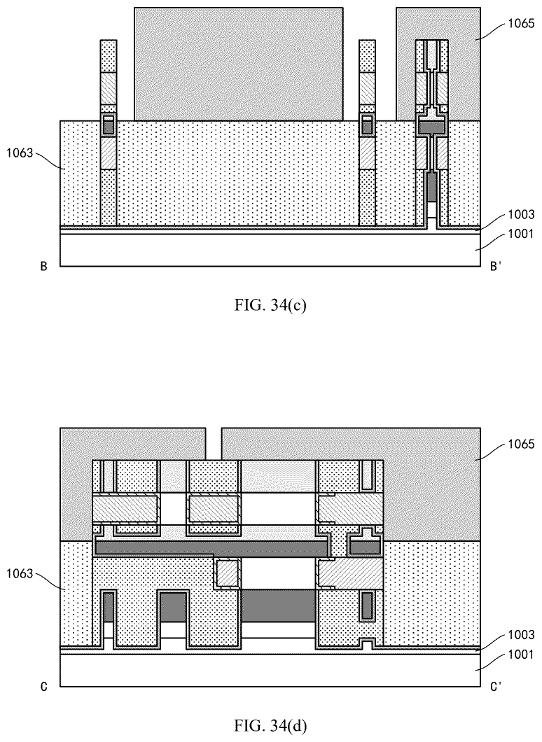

At this point, the gate electrode layer 1061′ in the upper layer extends continuously between the channel nanosheets in the upper layer. It is desired an isolation between the pull-down transistor and the pass-gate transistor, as well as between the transistors of the first group and the transistors of the second group. For example, as shown in FIGS. 34(a), 34(b), 34(c), and 34(d) (which are the top view and the cross-sectional views along line AA′, line BB′, and line CC′ respectively), a photoresist 1065 may be formed on the above structure and patterned to expose a region required to be isolated. Specifically, in the top view of FIG. 34(a), a region between the pull-down transistor PD-1 and the pass-gate transistor PG-1 may be exposed in the lower column; and a region between the pull-down transistor PD-2 and the pass-gate transistor PG-2 may be exposed in the upper column. In addition, a region between two groups (corresponding to the upper and lower columns) may also be exposed.

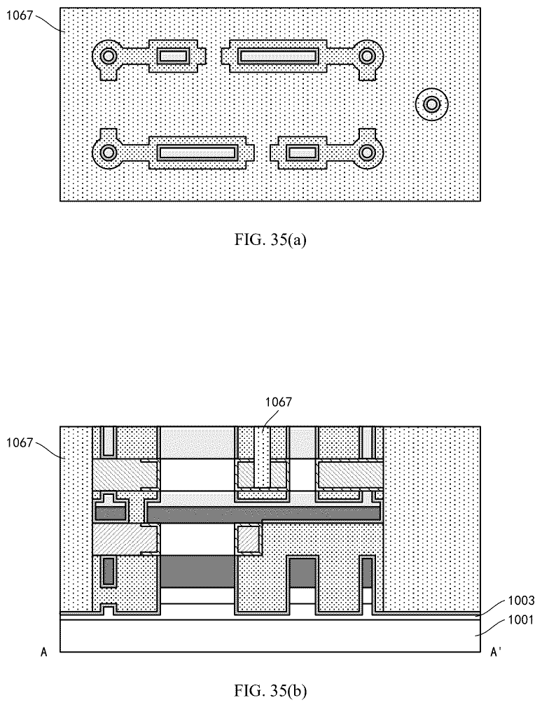

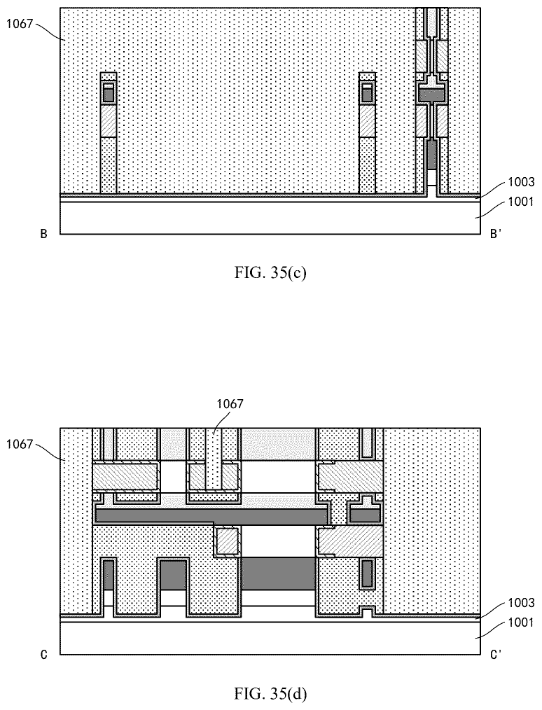

Then, as shown in FIGS. 35(a), 35(b), 35(c), and 35(d) (which are the top view and the cross-sectional views along line AA′, line BB′, and line CC′ respectively), the photoresist 1065 may be used as an etching mask to etch down layers (such as the occupying layer 1049, the gate dielectric layer 1057, and the gate electrode layer 1061′) by RIE until the gate electrode layer 1061′ is cut off. When the device size is small or the opening in the photoresist 1065 is small, the gate electrode layer 1061′ may be etched through isotropic etching, so that the gate electrode layer 1061′ below the occupying layer 1049 may be cut off through the undercut.

Accordingly, the gate electrode layer 1061′ may be divided into: a part for the first pull-down transistor PD-1, a part for the first pass-gate transistor PG-1, a part for the second pull-down transistor PD-2, and a part for the second pass-gate transistor PG-2 (please refer to FIG. 34(a)).

At this point, the fabrication of SRAM cells has been substantially completed. The gap on the substrate may be filled with an isolation layer by deposition followed by planarization such as CMP (which may stop at the occupying layer 1049). The isolation layer may include suitable dielectric materials such as oxides, and thus may be shown as the isolation layer 1067 along with the previous shielding layer 1063.

Here, contact plugs WL-1 and WL-2 may be formed.

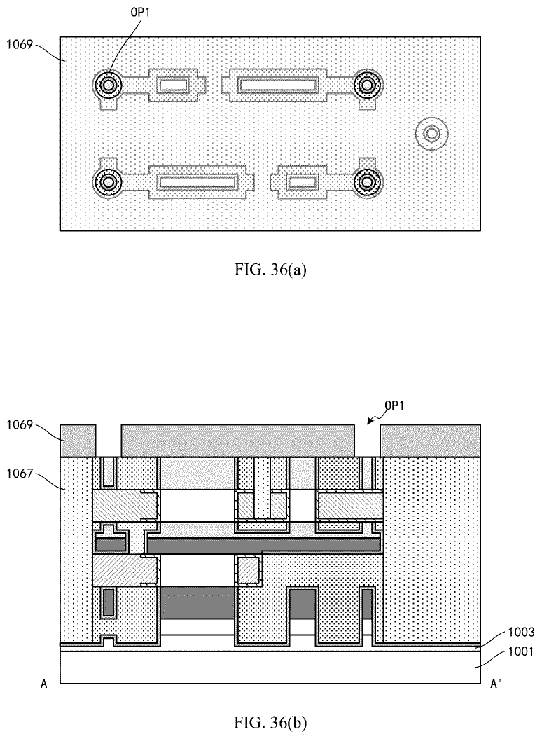

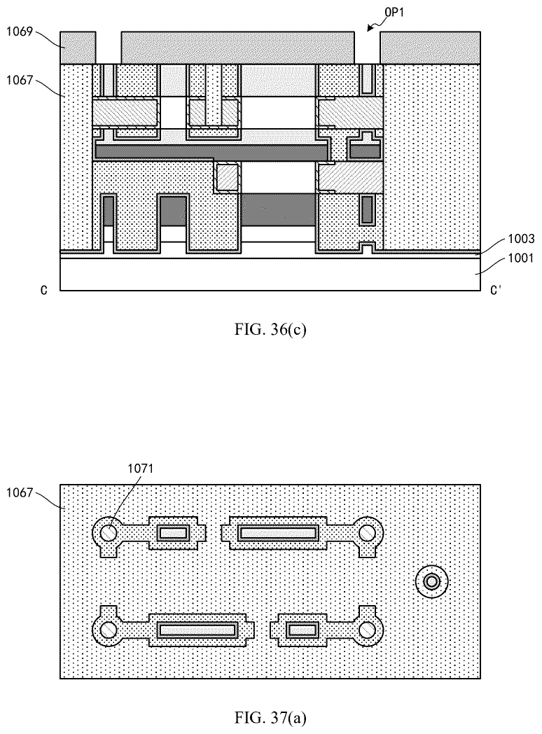

For example, as shown in FIGS. 36(a), 36(b), and 36(c) (which are the top view and the cross-sectional views along line AA′ and line CC′ respectively), a photoresist 1069 may be formed on the above structure and patterned to expose a region (relative corners of the rectangular pattern) where the contact plugs WL-1 and WL-2 are located, as shown as an opening OP1 in the figure. In this example, the region (the other two corners of the rectangular pattern) where the third interconnection structure V-1 and the fourth interconnection structure V-2 are located is also exposed. Contact plugs may be formed in this region for subsequent testing, but this is not necessary.

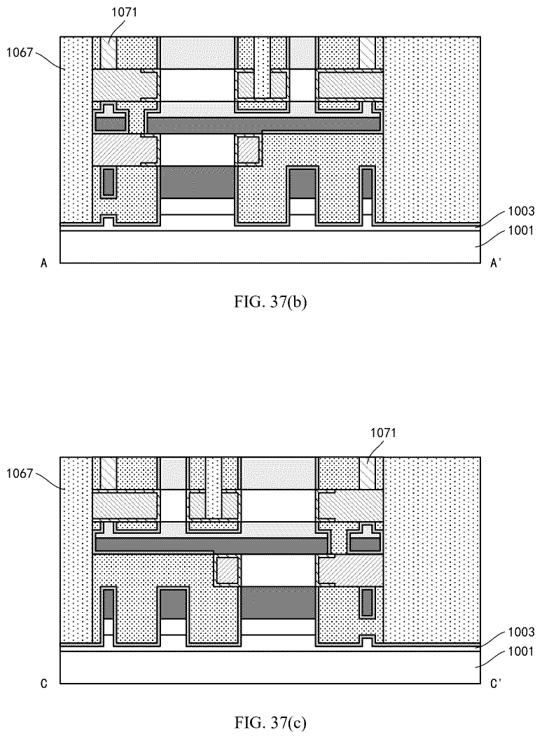

Then, as shown in FIGS. 37(a), 37(b), and 37(c) (which are the top view and the cross-sectional views along line AA′ and line CC′ respectively), layers (such as the second source/drain layer 1017, which may have been partially or completely converted to silicide, and the etching may be stopped at the gate dielectric layer 1057) may be etched downwards through the opening OP1 to expose the gate electrode layer 1061′. In this way, a contact hole to the gate electrode layer 1061′ is formed. The contact hole is defined by the corresponding nanowires in the second source/drain layer 1017, and thus be self-aligned with the gate electrode layer 1061′. The contact hole may be filled with conductive materials such as metal such as W, to form a contact plug 1071 (i.e., contact plugs WL-1 and WL-2).

Next, the interconnection structures, such as various via holes and wirings, may be fabricated, which will not be repeated here.

The SRAM cell according to embodiments of the present disclosure may be applied to various electronic devices. For example, a memory may be formed based on such SRAM cell, and an electronic device may be constructed accordingly. Therefore, the present disclosure further provides a memory including the above-mentioned SRAM cell and an electronic device including the memory. The electronic device may further include components such as a processor cooperated with the memory. Such electronic device may include, for example, a smart phone, a computer, a tablet computer (PC), a wearable intelligence device, and a mobile power supply.

The present disclosure further involves the following aspects.

1. A method of manufacturing a static random access memory (SRAM) cell, including:
providing, on a substrate, a stack of a first group of a first source/drain layer, a channel layer, and a second source/drain layer and a second group of a first source/drain layer, a channel layer, and a second source/drain layer sequentially;
forming a hard mask layer on the stack, wherein the hard mask layer includes main body parts and a connecting part between the main body parts, the main body parts are used to define transistors included in the SRAM cell, the connecting part is used to define an interconnection structure included in the SRAM cell, a line width of the connecting part is less than a line width of the main body part, the main body parts are in a rectangular shape, and at least one main body part may have a width different from other main body parts;
defining, in the channel layer and second source/drain layer of the second group, active regions of a pull-down transistor and a pass-gate transistor among the transistors included in the SRAM cell, by using the hard mask layer;
defining, in the first source/drain layer of the second group and the second source/drain layer of the first group, a first interconnection structure and a second interconnection structure among the interconnection structure included in the SRAM cell, by using the hard mask layer; and
defining, in the channel layer and first source/drain layer of the first group, an active region of a pull-up transistor among the transistors included in the SRAM cell, by using the hard mask layer.

2. The method according to the first aspect, wherein the hard mask layer further includes a further main body part for defining a third interconnection structure and a fourth interconnection structure in the interconnection structure.

3. The method according to the first or second aspect, wherein the hard mask layer further includes a further main body part for defining a contact plug to a gate electrode of the pass-gate transistor.

4. The method according to any one of the preceding aspects, wherein the hard mask layer has an overall shape of rectangle or parallelogram.

5. The method according to any one of the preceding aspects, wherein the hard mask layer further includes a further main body part for defining a contact plug used to apply a power supply voltage to the first source/drain layer of the first group.

6. The method according to any one of the preceding aspects, wherein when defining the active regions in the channel layer of the second group and the channel layer of the first group, a part of the channel layer is removed at a position where it is not needed.

7. The method according to any one of the preceding aspects, wherein defining the active region in the channel layer of the second group includes:
selectively etching the second source/drain layer and channel layer of the second group in sequence, by using the hard mask layer as an etching mask;
further selective etching the channel layer of the second group, so that the channel layer of the second group is divided into separate parts corresponding to the main body parts in the hard mask layer respectively; and
forming a sacrificial gate at a periphery of each of the separate parts of the channel layer of the second group, based on the hard mask layer.

8. The method according to the seventh aspect, wherein defining the active region in the second source/drain layer of the second group includes:
further selective etching the second source/drain layer of the second group, so that the second source/drain layer of the second group is divided into separate parts corresponding to the main body parts in the hard mask layer respectively; and
forming an occupying layer at a periphery of each of the separate parts of the second source/drain layer of the second group, based on the hard mask layer.

9. The method according to the seventh or eighth aspect, wherein defining the first interconnection structure and the second interconnection structure in the first source/drain layer of the second group and the second source/drain layer of the first group includes:
selectively etching the first source/drain layer of the second group and the second source/drain layer of the first group in sequence, by using the hard mask layer as the etching mask.

10. The method according to any one of seventh to ninth aspects, wherein defining the active region in the channel layer of the first group includes:
selectively etching the channel layer of the first group by using the hard mask layer as the etching mask;
further selective etching the channel layer of the first group, so that the channel layer of the first group is divided into separate parts corresponding to the main body parts in the hard mask layer respectively.

11. The method according to the tenth aspect, further including:
forming an occupying layer at a periphery of each of the separate parts of the channel layer of the first group according to an arrangement of the pull-up transistor in the SRAM cell, based on the hard mask layer; and
forming a sacrificial gate at the periphery of each of the separate parts of the channel layer of the first group, based on the hard mask layer.

12. The method according to the tenth aspect, wherein defining the first interconnection structure and the second interconnection structure in the first source/drain layer of the second group and the second source/drain layer of the first group further includes:
achieving an electrical isolation in the first source/drain layer of the second group and the second source/drain layer of the first group, so as to divide the first source/drain layer of the second group and the second source/drain layer of the first group into parts electrically isolated from each other and corresponding to the first interconnection structure and the second interconnection structure.

13. The method according to any one of seventh to twelfth aspects, wherein defining the active region in the first source/drain layer of the first group includes:
selectively etching the first source/drain layer of the first group by using the hard mask layer as the etching mask;
further selective etching the first source/drain layer of the first group, so that the first source/drain layer of the first group is divided into separate parts corresponding to the main body parts in the hard mask layer respectively; and
forming an occupying layer at a periphery of each of the separate parts of the first source/drain layer of the first group, based on the hard mask layer.

14. The method according to any one of the preceding aspects, further including: providing an isolation auxiliary layer on the substrate, wherein the stack is provided on the isolation auxiliary layer,
wherein the method further includes:
selectively etching the isolation auxiliary layer by using the hard mask layer as the etching mask; and
removing a part of the isolation auxiliary layer at a position where a third interconnection structure and a fourth interconnection structure are located.

15. The method according to any one of the preceding aspects, further including:
removing an occupying layer and silicifying an exposed part of the source/drain layer.

16. The method according to any one of the preceding aspects, further including:
locally removing the sacrificial gate at a position where a contact plug used to apply a power supply voltage to the first source/drain layer of the first group is located, and silicifying an exposed part of the channel layer.

17. The method according to any one of the preceding aspects, further including:
replacing the sacrificial gate with a gate stack.

In the above descriptions, technical details such as patterning and etching of each layer have not been described in detail. However, those skilled in the art should understand that various technical means may be used to form layers, regions, etc. of desired shapes. In addition, in order to form the same structure, those skilled in the art may further design a method that is not completely the same as the method described above. In addition, although the various embodiments are described above separately, this does not mean that the measures in the various embodiments may not be advantageously used in combination.

Embodiments of the present disclosure have been described above. However, these embodiments are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

What is claimed is:

1. A static random access memory SRAM cell, comprising: a first pull-up transistor, a second pull-up transistor, a first pull-down transistor, a second pull-down transistor, a first pass-gate transistor, and a second pass-gate transistor on a substrate,
wherein the first pull-up transistor and the second pull-up transistor are provided at a first height relative to the substrate,
wherein the first pull-down transistor, the second pull-down transistor, the first pass-gate transistor, and the second pass-gate transistor are provided at a second height different from the first height relative to the substrate,
wherein each of the first pull-up transistor, the second pull-up transistor, the first pull-down transistor, the second pull-down transistor, the first pass-gate transistor, and the second pass-gate transistor comprises a channel nanosheet extending in a first direction substantially parallel to a surface of the substrate, as well as source/drain portions provided above and below the channel nanosheet respectively, and
wherein the first pull-down transistor is aligned with the first pull-up transistor in a vertical direction, and the second pull-down transistor is aligned with the second pull-up transistor in the vertical direction.

2. The SRAM cell according to claim 1, wherein a width of at least one of the channel nanosheets of the first pull-down transistor, the second pull-down transistor, the first pass-gate transistor, and the second pass-gate transistor in the first direction is different from widths of other channel nanosheets in the first direction.

3. The SRAM cell according to claim 2,
wherein the channel nanosheet of each of the first pull-down transistor and the second pull-down transistor has a first width in the first direction, and
wherein the channel nanosheet of each of the first pass-gate transistor and the second pass-gate transistor has a second width different from the first width in the first direction.

4. The SRAM cell according to claim 3, wherein the first width is greater than the second width.

5. The SRAM cell according to claim 1, wherein the channel nanosheets of the first pull-down transistor, the second pull-down transistor, the first pass-gate transistor, and the second pass-gate transistor have substantially a same width in the first direction.

6. The SRAM cell according to claim 1,
wherein a width of the channel nanosheet of the first pull-up transistor in the first direction is substantially the same as a width of the channel nanosheet of the first pull-down transistor in the first direction, and
wherein a width of the channel nanosheet of the second pull-up transistor in the first direction is substantially the same as a width of the channel nanosheet of the second pull-down transistor in the first direction.

7. The SRAM cell according to claim 1, further comprising:
a first interconnection structure comprising a first segment extending in the first direction and a second segment extending in a second direction intersecting with the first direction, wherein the first segment and the second segment are connected to each other, the first segment comprises a first source/drain portion self-aligned with the channel nanosheet of the first pull-down transistor, a second source/drain portion self-aligned with the channel nanosheet of the first pass-gate transistor, and a third source/drain portion self-aligned with the channel nanosheet of the first pull-up transistor;
a second interconnection structure comprising a third segment extending in the first direction and a fourth segment extending in the second direction, wherein the third segment and the fourth segment are connected to each other, the third segment comprises a fourth source/drain portion self-aligned with the channel nanosheet of the second pull-down transistor, a fifth source/drain portion self-aligned with the channel nanosheet of the second pass-gate transistor, and a sixth source/drain portion self-aligned with the channel nanosheet of the second pull-up transistor,
wherein in a plan view, the first interconnection structure and the second interconnection structure are opposed to each other to substantially form a quadrilateral shape such as a rectangle, wherein the quadrilateral shape comprises a first side corresponding to the first segment, a second side corresponding to the second segment, a third side corresponding to the third segment, and a fourth side corresponding to the fourth segment.

8. The SRAM cell according to claim 7, further comprising:
a third interconnection structure integrated with the second interconnection structure and electrically connected to a gate electrode of the first pull-up transistor and a gate electrode of the first pull-down transistor;
a fourth interconnection structure integrated with the first interconnection structure and electrically connected to a gate electrode of the second pull-up transistor and a gate electrode of the second pull-down transistor.

9. The SRAM cell according to claim 8,
wherein the third interconnection structure is located at an intersection of the first side and the fourth side, and the fourth interconnection structure is located at an intersection of the third side and the second side,
wherein in a top view, the third interconnection structure, the first source/drain portion, and the second source/drain portion are arranged in sequence on the first side, and
wherein in the top view, the fourth interconnection structure, the fourth source/drain portion, and the fifth source/drain portion are arranged in sequence on the third side.

10. The SRAM cell according to claim 9, wherein in the top view, the gate electrode of each of the first pull-up transistor, the second pull-up transistor, the first pull-down transistor, the second pull-down transistor, the first pass-gate transistor, and the second pass-gate transistor extends along some of the first side, the second side, the third side, and the fourth side.

11. The SRAM cell according to claim 10,
wherein the gate electrode of the first pull-down transistor extends along the first side and the fourth side, surrounds a periphery of the channel nanosheet of the first pull-down transistor, and is in contact with the third interconnection structure;
wherein the gate electrode of the second pull-down transistor extends along the third side and the second side, surrounds a periphery of the channel nanosheet of the second pull-down transistor, and is in contact with the fourth interconnection structure;
wherein the gate electrode of the first pull-up transistor extends along the first side and the fourth side, surrounds a periphery of the channel nanosheet of the first pull-up transistor, and is in contact with the third interconnection structure; and
wherein the gate electrode of the second pull-up transistor extends along the third side and the second side, surrounds a periphery of the channel nanosheet of the second pull-up transistor, and is in contact with the fourth interconnection structure.

12. The SRAM cell according to claim 11,
wherein the gate electrode of the first pass-gate transistor extends along the first side and the second side and surrounds a periphery of the channel nanosheet of the first pass-gate transistor;
wherein the gate electrode of the second pass-gate transistor extends along the third side and the fourth side and surrounds a periphery of the channel nanosheet of the second pass-gate transistor;
wherein the SRAM cell further comprises:
a first contact plug for the gate electrode of the first pass-gate transistor, wherein the first contact plug is self-aligned at an intersection of the first side and the second side; and
a second contact plug for the gate electrode of the second pass-gate transistor, wherein the second contact plug is self-aligned at an intersection of the third side and the fourth side.

13. The SRAM cell according to claim 10, wherein the gate electrode of each of the first pull-up transistor, the second pull-up transistor, the first pull-down transistor, the second pull-down transistor, the first pass-gate transistor, and the second pass-gate transistor is self-aligned with corresponding channel nanosheet.

14. The SRAM cell according to claim 7,
wherein the first pull-down transistor further comprises a seventh source/drain portion self-aligned with the channel nanosheet of the first pull-down transistor, the first pass-gate transistor further comprises an eighth source/drain portion self-aligned with the channel nanosheet of the first pass-gate transistor, and the seventh source/drain portion and the eighth source/drain portion extend in the first side and are spaced apart from each other,
wherein the second pull-down transistor further comprises a ninth source/drain portion self-aligned with the channel nanosheet of the second pull-down transistor, the second pass-gate transistor further comprises a tenth source/drain portion self-aligned with the channel nanosheet of the second pass-gate transistor, and the ninth source/drain portion and the tenth source/drain portion extend in the third side and are spaced apart from each other.

15. The SRAM cell according to claim 14,
wherein the first pull-up transistor further comprises an eleventh source/drain portion self-aligned with the channel nanosheet of the first pull-up transistor,
wherein the second pull-up transistor further comprises a twelfth source/drain portion self-aligned with the channel nanosheet of the second pull-up transistor,
wherein the SRAM cell further comprises:
a contact layer; and
a third contact plug provided on the contact layer,
wherein the eleventh source/drain portion and the twelfth source/drain portion are electrically connected to the third contact plug via the contact layer, wherein the third contact plug comprises:
a first part at substantially the same height as the seventh source/drain portion, the eighth source/drain portion, the ninth source/drain portion, and the tenth source/drain portion, wherein the first part comprises a semiconductor element contained in the seventh source/drain portion, the eighth source/drain portion, the ninth source/drain portion, and the tenth source/drain portion;
a second part at substantially the same height as the channel nanosheets of the first pull-down transistor, the second pull-down transistor, the first pass-gate transistor, and the second pass-gate transistor, wherein the second part comprises a semiconductor element contained in the channel nanosheets of the first pull-down transistor, the second pull-down transistor, the first pass-gate transistor, and the second pass-gate transistor;
a third part at substantially the same height as the first interconnection structure and the second interconnection structure, wherein the third part comprises a semiconductor element contained in the first interconnection structure and the second interconnection structure;
a fourth part at substantially the same height as the channel nanosheets of the first pull-up transistor and the second pull-up transistor, wherein the fourth part comprises a semiconductor element contained in the channel nanosheets of the first pull-up transistor and the second pull-up transistor; and
a fifth part at substantially the same height as the eleventh source/drain portion and the twelfth source/drain portion, wherein the fifth part comprises a semiconductor element contained in the eleventh source/drain portion and the twelfth source/drain portion,
wherein the first part, the second part, the third part, the fourth part, and the fifth part are aligned in the vertical direction.

16. A memory, comprising a plurality of SRAM cells according to claim 1.

17. An electronic device, comprising the memory according to claim 16 and a processor operationally coupled with the memory.

18. The electronic device according to claim 17, wherein the electronic device comprises: a smart phone, a computer, a tablet computer, a wearable intelligence device, an artificial intelligence device, or a mobile power supply.
